(19) United States
(12) Patent Application Publication
(10) Pub. No.: US 2024/0426603 A1
(43) Pub. Date: Dec. 26, 2024

(54) OPTICAL DEVICE, METHOD FOR MEASURING AN ACTUAL TILT OF AN OPTICAL SURFACE OF AN OPTICAL ELEMENT, AND LITHOGRAPHY SYSTEM

(71) Applicant: Carl Zeiss SMT GmbH, Oberkochen (DE)

(72) Inventors: Heiner ZWICKEL, Karlsruhe (DE); Tobias HARTER, Karlsruhe (DE); Matthias HILLENBRAND, Jena (DE); Stefan RICHTER, Jena (DE); Ralf AMELING, Aalen (DE); Fabian HAACKER, Aalen (DE)

(21) Appl. No.: 18/829,619

(22) Filed: Sep. 10, 2024

Related U.S. Application Data
(63) Continuation of application No. PCT/EP2023/057356, filed on Mar. 22, 2023.

(30) Foreign Application Priority Data
Mar. 25, 2022 (DE) 10 2022 202 989.5

(51) Int. Cl. G01B 11/26; G03F 7/00

(52) U.S. Cl. CPC G01B 11/26; G03F 7/70316; G03F 7/70591; G03F 7/7085

(57) ABSTRACT

An optical device, such as for a lithography system, comprises: at least one optical element having at least one optical surface; one or more actuators to tilt the optical surface of the optical element; and a measuring device to detect a tilt of the optical surface from an idle position. The measuring device has at least one waveguide which forms a closed measuring section. The waveguide is designed for coupling in and propagating one or more modes of a measuring beam. The waveguide is arranged such that a tilt of the optical surface influences the measuring beam propagating through the waveguide. The measuring device is designed to detect an influencing of the measuring beam caused by the tilt of the optical surface.

### CROSS-REFERENCE TO RELATED APPLICATIONS

The present application is a continuation of, and claims benefit under 35 USC 120 to, international application No. PCT/EP2023/057356, filed Mar. 22, 2023, which claims benefit under 35 USC 119 of German Application No. 10 2022 202 989.5, filed Mar. 25, 2022. The entire disclosure of each of these applications is incorporated by reference herein.

### FIELD

The disclosure relates to an optical apparatus, such as an optical apparatus for a lithography system, having at least one optical element comprising at least one optical surface and having one or more actuators for tilting the optical surface of the optical element and having a measuring device for sensing a tilt of the optical surface from a rest position. The disclosure also relates to a method for measuring an actual tilt of an optical surface of an optical element, such as of an optical element of a lithography system, with the actual tilt of the optical surface being determined by at least one measurement beam which propagates along a measurement section, with one or more actuators being arranged to influence the tilt of the optical surface. Moreover, the disclosure relates to a lithography system, such as a projection exposure apparatus for semiconductor lithography, having an illumination system with a radiation source and an optical unit which comprises at least one optical element.

### BACKGROUND

Optical elements for guiding and shaping radiation in projection exposure apparatuses are known. In certain known optical elements, an optical surface of the optical element guides and shapes the light waves incident on the optical element. To form an exact and precisely aligned wavefront with desired properties, precise control of the surface alignment or tilt is typically desirable.

Integrating optical elements in optical apparatuses, which comprise actuators for force production in order to tilt, in a targeted manner, such that the optical surface that interacts with the light waves has been disclosed.

The effect of the actuators on the optical surface has been predicted, for example on the basis of modeling. Influences neglected in the modeling may weaken a predictive power of the model.

### SUMMARY

To meet the continually increasing demands in relation to increasing precision, it is desirable that the actual tilt of the optical surface corresponds to the desired target tilt as exactly as possible. To this end, it is desirable to determine the respective actual tilt as exactly as possible. With regards to a further increase in precision, the known measures for exactly determining the actual tilt could be deemed inadequate.

The present disclosure seeks to allow for relatively precise and reliable determination of an actual tilt of an optical surface.

In an aspect, the disclosure provides an optical apparatus, such as for a lithography system, having at least one optical element comprising at least one optical surface and having one or more actuators for tilting the optical surface of the optical element and having a measuring device for sensing a tilt of the optical surface from a rest position. The measuring device comprises at least one waveguide which forms a closed measurement section, with the waveguide being configured to input couple and allow propagation of one or more modes of a measurement beam and with the waveguide being arranged such that a tilt of the optical surface influences the measurement beam propagating through the waveguide, with the measuring device being configured to sense an influence on the measurement beam caused by the tilt of the optical surface.

The present disclosure seeks to provide a method for measuring an actual tilt of an optical surface which enables precise and reliable measurement of an actual tilt of the optical surface.

In an aspect, the disclosure provides a method for measuring an actual tilt of an optical surface of an optical element, for example of a lithography system, with the actual tilt of the optical surface being determined by at least one measurement beam which propagates along a measurement section, with one or more actuators being arranged to influence the tilt of the optical surface. A closed measurement section is formed by at least one waveguide, with the measurement beam being input coupled into the waveguide such that one or more modes of the measurement beam propagate through the waveguide, with the waveguide being arranged such that the measurement beam propagating through the waveguide is influenced by a tilt of the optical surface, with the influence on the measurement beam caused by the tilt of the optical surface being sensed and the actual tilt of the optical surface being determined therefrom.

The present disclosure seeks to provide a lithography system which enables forming precisely aligned wavefronts.

In an aspect, the disclosure provides a lithography system, such as a projection exposure apparatus for semiconductor lithography, having an illumination system with a radiation source and an optical unit which comprises at least one optical element. At least one optical apparatus as disclosed herein is provided, with at least one of the optical elements being an optical element of the at least one optical apparatus, and/or at least one of the optical elements comprises an optical surface, the actual tilt of which is ascertained using a method according to the disclosure.

The optical apparatus according to the disclosure can be suitable for a lithography system. The optical apparatus according to the disclosure can comprise at least one optical element comprising at least one optical surface. Further, the optical apparatus according to the disclosure can comprise one or more actuators for tilting the optical surface of the optical element, and a measuring device for sensing a tilt of the optical surface from a rest position. According to the disclosure, provision can be made for the measuring device to comprise at least one waveguide which forms a closed measurement section, with the waveguide being configured to input couple and allow propagation of one or more modes of a measurement beam. Further, provision can be made for the waveguide to be arranged such that a tilt of the optical surface influences the measurement beam propagating through the waveguide, with the measuring device being configured to sense an influence on the measurement beam caused by the tilt of the surface.

Within the scope of the disclosure, a waveguide should be understood to mean a device which, at every point, interacts in such a way with an electromagnetic wave propagating within the waveguide that the propagation direction of the electromagnetic radiation or wave is determined by the waveguide.

Within the scope of the disclosure, a measurement beam is understood to mean a mode of an electromagnetic wave, for example of a light wave, optionally propagating in a waveguide.

Within the scope of the disclosure, a closed measurement section can be understood to mean a measurement section formed by a waveguide in the form of a channel closed all round, within which the measurement beam propagates. The channel interior need not be hollow in this context. The channel walls might also differ from a channel interior in terms of a refractive index.

Within the scope of the disclosure, provision is made for the entire measurement section to be in the form of a waveguide-based measurement section. For example, the closed measurement section does not comprise any portions in which the measurement beam propagates as a free beam.

In such a closed construction of the measurement section, which only admits a one-dimensional propagation of the measurement beam, the measurement section can be shielded from an ingress of electromagnetic waves. In other words, this for example can help prevent a contamination of the measurement beam by stray light.

Further, a measurement section should be understood to mean that portion of the path of propagation of the measurement beam in which the measurement beam experiences the influence to be measured, with the measuring device being configured to measure the influence on the measurement beam experienced in the measurement section.

An optical apparatus according to the disclosure can comprise an optical element with an optical surface. However, an optical apparatus according to the disclosure might also comprise a plurality of optical elements. Further, the one or more optical elements might also have more than only one optical surface.

An optical apparatus according to the disclosure can allow for the tilt of the optical surface to be monitored exactly and reliably via the measuring device.

In this case, information about tilts of the optical surface can be collected and sensed via the measuring device in tight spatial and/or functional proximity of the optical element.

Monitoring the actual tilt of the optical surface or information relating to the actual tilt of the optical surface can provide knowledge about the alignment of the optical surface and hence knowledge about its effect on light or radiation guided and shaped by the optical surface. This can allow conclusions to be drawn, at least indirectly, about the effect obtained at the optical surface due to the actuators configured to tilt the optical surface.

The use of waveguides and measurement beams, i.e., an optical sensor system in general, as part of the measuring device means that the optical apparatus according to the disclosure means that the measuring device can be formed in a manner less sensitive to temperature variations as a result. For example, the use of an optical sensor system allows compensation of measurement errors induced by temperature variations. The optical sensor system-based measuring device of the optical apparatus according to the disclosure is also not disturbed by a plasma environment present in the EUV projection exposure apparatus, and also has great sensitivity at the same time.

Provision can be made for the at least one actuator of the optical apparatus to be formed as a piezo element, for example as a piezoelectric layer, and/or as a comb electrode.

In a development of the optical apparatus according to the disclosure, provision can be made for provision to be made of a radiation source for forming a measurement radiation, optionally a coherent measurement radiation, serving to form the measurement beam.

If the radiation source is provided as part of the optical apparatus, then this can realize a structure of the optical apparatus that is as integrated as possible, for example a monolithic structure. For example, the radiation source might be integrated in a chip on which the optical apparatus is formed.

The radiation source can be formed as part of the optical apparatus. However, the radiation source need not necessarily be part of the optical apparatus. The measurement radiation provided to form the measurement beam can be created in a suitable manner without a radiation source needing to be part of the optical apparatus.

If the radiation source supplies coherent light, then the tilt can be determined precisely by exploiting interference phenomena.

The measuring device may comprise a photonic circuit, optionally a photonic integrated circuit, and/or be in the form of a photonic circuit, optionally a photonic integrated circuit.

A beam steering device, optionally at least one active electro-optic modulator (EOM), might be provided, the latter optionally being formed in the photonic circuit of the measuring device in integrated fashion.

Provision can be made for a single radiation source to be provided for the purpose of creating the measurement radiation and for measurement beams to be distributed among a plurality of measurement sections via the beam steering device, for example via the active electro-optic modulator.

Provision can be made for the measurement radiation to be modulated depending on the measurement section to be fed with the measurement beam, and for the measurement radiation to be subsequently re-combinable in a common waveguide fiber. In this context, the modulation can allow a distinction to be made between individual measurement sections.

Further, targeted switching of individual measurement sections might be allowed by the use of the beam steering device, optionally the active electro-optic modulator.

In a development of the optical apparatus according to the disclosure, provision can be made for the waveguide to be configured to allow propagation of one or more modes of a coherent measurement beam.

If the waveguide is configured to allow propagation of one or more modes of a coherent measurement beam, then using coherent measurement radiation, such as in the form of interference phenomena, can be exploited.

In a development of the optical apparatus according to the disclosure, provision can be made for
the at least one actuator to be formed as a microelectromechanical system and/or
the at least one optical element to be formed as a micromirror and/or
the radiation source to be formed in monolithically integrated fashion.

The optical apparatus according to the disclosure can be suitable if the at least one actuator is in the form of a microelectromechanical system (MEMS). As a result, the optical apparatus can have a compact structure.

The optical apparatus according to the disclosure can be suitable if the at least one optical element is in the form of a micromirror. Optionally, the optical apparatus comprises optical elements in the form of micromirrors or individual mirrors for a field facet mirror or a pupil facet mirror—these will be described below—which may comprise a multiplicity of optical elements. Optionally, a plurality of optical elements, optionally all optical elements, of the facet mirror or pupil facet mirror are in the form of optical elements of the optical apparatus according to the disclosure.

It can be desirable for each micromirror of a field facet mirror or pupil facet mirror to be in the form of an optical element of an optical apparatus according to the disclosure. That is to say, an appropriate number of optical apparatuses according to the disclosure are realized in a field facet mirror and/or pupil facet mirror comprising a plurality of micromirrors. In general, it is naturally also possible for only some of the micromirrors to be in the form of optical elements of an apparatus according to the disclosure. Further, provision can be made for the optical apparatus according to the disclosure to comprise a plurality of optical elements which are each in the form of a micromirror for a field facet mirror or a pupil facet mirror.

A monolithic integration of the radiation source means that a relative displacement of the radiation source in relation to the waveguide and/or in relation to the measuring device, for example on account of drift, is minimized.

Notably, aspects arise in respect of the installation space and a simple replaceability if the at least one actuator is in the form of a microelectromechanical system and the at least one optical element is in the form of a micromirror and the radiation source is formed in monolithically integrated fashion.

Provision can be made for the optical elements or the micromirror to have a maximum spatial extent of 100 μm.

In a development of the optical apparatus according to the disclosure, provision can be made for the at least one waveguide to be arranged such that the actual tilt of the optical surface is determinable by way of a measurement of the translation or deformation of the optical element or of an element connected to the optical element.

If the measurement of the actual tilt of the optical surface can be reduced to a measurement of the translation or deformation of the optical element or of an element connected to the optical element, then this can allow a precise determination of the actual tilt since translations and/or deformations can be determined with high precision in the smallest of spaces.

Further, provision can be made for a direction or a polarity of the actual tilt to be ascertainable from a measurement of the translation and/or deformation.

For example, if the deformation is a compression, then this can yield a shortening of the measurement section. If the position of the measurement section is known, for example in a connected element, optionally in a spring element, then this can allow the direction in which the spring element is deflected and hence the direction in which the optical surface is tilted to be deduced.

In a development of the optical apparatus according to the disclosure, provision can be made for the measurement section to be arranged at least in part in and/or on the optical element and/or for the measurement section to be arranged at least in part in and/or on the element connected to the optical element.

If the measurement section is arranged at least in part in or on the optical element, then this can yield strong and reliable mechanical coupling of the measurement section to the optical element, whereby a tilt of the optical surface is able to be sensed precisely.

In an alternative to that, tight mechanical coupling can also be achieved by virtue of the measurement section being arranged at least in part in or on the element connected to the optical element. This can yield indirect mechanical coupling between the measurement section and the optical element; however, this also supplies reliable data in the case of a tight mechanical coupling between the connected element and the optical element.

In a development of the optical apparatus according to the disclosure, provision can be made for the connected element to be a spring element, to which the optical element is connected at least indirectly and/or on which the optical element is arranged and/or formed.

If the connected element is a spring element, to which the optical element is connected at least indirectly and/or on which the optical element is arranged and/or formed, then this can result in the above-described at least indirect mechanical coupling of the measurement section to the optical element. For example, the connected element in the form of a spring element imparts restoring forces which act on the optical surface of the optical element and, for example on account of Hooke's law, standing deformations of the spring element have a tight deterministic relationship with the tilt of the optical surface.

Provision can be made for a photonic integrated circuit to be integrated in the spring element. As a result of the spring element bending, the at least one waveguide in this circuit experiences mechanical stress and/or a directed compression and/or stretching.

Provision can be made for the at least one waveguide to be aligned such that the length of the waveguide changes as a result of a compression and/or stretching of the spring element.

In an alternative to that or in addition, provision can be made for the waveguide to be designed such that the measurement beam is influenced by an elasto-optical effect, in which an effective mode index of the waveguide changes on account of mechanical stress caused by the compression and/or stretching.

Provision can be made for the integrated photonic circuit to comprise an interferometric and/or resonant measurement section, which is able to detect this change in length sufficiently sensitively.

In a development of the optical apparatus according to the disclosure, provision can be made for the measuring device to comprise a path length measuring device for sensing a change in length of the measurement section provided by the waveguide, and for the measuring device to be configured to determine the actual tilt of the optical surface from the change in length.

If the measurement of the tilt can be reduced to sensing the change in length of the measurement section provided by the waveguide, which is sensed by a path length measuring device of the measuring device, then it is possible to use the indifference of the optionally coherent measurement radiation for ascertaining the path length, for example.

In a development of the optical apparatus according to the disclosure, provision can be made for the path length measuring device to be configured to split the optionally coherent measurement radiation into at least two measurement beams and make these interfere and/or create a measurement spectrum of the measurement radiation.

If the path length measuring device is configured to split the optionally coherent measurement radiation into at least two measurement beams and configured to make these beams interfere, then the tilt can be represented for example by a change in the optical path lengths of one of the two measurement beams. If the two measurement beams are superimposed at different tilts, then different interference patterns between the two measurement beams arise on account of different path length differences in each case. This may happen in the case of measurement beams from a coherent measurement radiation.

In an alternative to that or in addition, the path length measuring device may be configured to create a measurement spectrum of the measurement radiation, which may contain information about the path length change caused by the tilt.

Provision can be made for the measuring device to comprise a Mach-Zehnder interferometer.

Provision can be made for the measuring device to comprise at least two waveguides, with
at least a first waveguide being arranged in a first region which is deformed when the optical surface is tilted, for example arranged in a first flexible region of the spring element, with
at least one second waveguide being arranged in a second region such that a tilt of the optical surface brings about a phase offset between a first measurement beam propagating in the first waveguide and a second measurement beam propagating in the second waveguide.

In this case, the first region and the second region might also overlap and/or be identical.

An extent of the tilt can be deduced on account of the fact that the first and the second measurement beam propagating through the first and the second waveguide accumulate different phases in the case of a tilt of the optical surface.

For example, provision can be made for the waveguides to be arranged and designed such that the phase offset between the first and the second measurement beam is bijectively, optionally proportionally, associable with a tilt angle of the optical surface.

In a development of the optical apparatus according to the disclosure, provision can be made for the measuring device to comprise at least two waveguides, with
at least a first waveguide being arranged in a first region which is deformed when the optical surface is tilted, for example arranged in a first flexible region of the spring element, with
at least a second waveguide being arranged in a second region which is deformed differently to the first region or not deformed when the optical surface is tilted, with
the waveguides optionally being arranged in a common plane.

The second region can be a flexible region of the spring element.

As a result of the first and the second region being deformed in different ways, for example to different extents, in the case of an optical surface tilt, measurement beams optionally propagating through the first and the second waveguide each accumulate different phases in the case of an optical surface tilt. From this, it is possible to deduce an extent of the tilt.

In other words, a differential phase accumulation of the measurement beams can be brought about by way of a differential deformation of the regions in which the first and the second waveguide are arranged. This allows an effect of the optical surface tilt on the first and the second region to be distinguished from effects acting globally on both regions to the same extent. The tilt actually present can then be deduced on the basis of mechanical simulations or calibration data records.

For example, provision can be made for the measuring device to comprise at least two waveguides, with
at least a first waveguide being arranged in a region which is deformed when the optical surface is tilted, for example arranged in a flexible region of the spring element, and with
at least a second waveguide being arranged in a region which is stiff or not deformed when the optical surface is tilted, for example arranged in a stiff region of the optical element, with
the waveguides optionally being arranged in a common plane.

If, in the case of a plurality of waveguides, at least one of the waveguides is arranged in a deformable region which is affected by a deformation in the case of a surface tilt and at least one other waveguide is arranged in a stiff region which remains non-deformed or is stiff in the case of a surface tilt, then a degree of deformation of the deformable region can be determined by way of for example a superposition of measurement beams propagating in the respective waveguides since only one of the two waveguides is affected by the deformation and experiences for example a change in length as a result. Accordingly, an interference pattern of the measurement beams from the respective waveguides changes with the degree of deformation of the region deformed by the tilt.

An arrangement in a common plane means that distortions not caused by the tilt act on the waveguides to the same extent.

As described above, the second waveguide need not necessarily be attached to a stiff region. Different strains on the two waveguides may be sufficient. Even a differential behavior, in which one waveguide is stretched and the other is compressed, can be used.

In a development of the optical apparatus according to the disclosure, provision can be made for the path length measuring device to comprise at least one grating device for the measurement radiation, with optionally the at least one grating device being formed as a fiber Bragg grating.

Within the scope of the disclosure, the term fiber Bragg grating should not be understood as restricted to optical fibers. For example, the term fiber Bragg grating should also be understood to mean a Bragg grating, for example a refractive index-varying Bragg grating, which is formed in a waveguide that is not an optical fiber.

For example, an optical grating device is suitable for the creation of a measurement spectrum. For example, the use of a fiber Bragg grating allows access to reliable technology for measuring path length changes.

In place of the above-described embodiment of the measurement section as an interferometric structure, it is also possible to form, for example structure, grating structures, especially Bragg grating structures, in the integrally formed waveguide. In the case of a mechanical deformation of the waveguides structured thus, there is a change in a grating period of the grating structures and in a refractive index in the waveguides. For example, certain wavelengths, at which a minimum and/or a maximum occurs in reflected and/or transmitted wavelength spectra, may be linked to a fixed grating period. If the grating period changes-possibly due to the mechanical deformation—there is also a change in spectral positions of the minima and/or maxima, and these can be read with the aid of a spectrally broadband radiation source and/or a spectrally tunable radiation source.

Provision can be made for the measuring device to comprise both interferometric structures and grating structures.

Temperature sensors and/or gas sensors, which can be based on resonator structures and/or interferometer structures, can also be provided in addition to the measurement section or sections of the measuring device. These structures can be integrated in the photonic circuit and can be used to compensate disturbances.

In a development of the optical apparatus according to the disclosure, provision can be made for the measuring device to comprise a plurality of waveguides which each form a closed measurement section, with at least two waveguides being formed at different depths in the spring element.

If the measuring device comprises a plurality of waveguides that each form a closed measurement section, with at least two waveguides being formed at different depths in the spring element, then different amounts of strain on the spring element in different layers can be used to exactly determine the deflection of the spring and hence the tilt of the optical surface.

In a development of the optical apparatus according to the disclosure, provision can be made for at least one of the waveguides to be arranged in a strain-neutral plane of the spring element and at least one of the waveguides to be arranged in or on the spring element such that the length of the waveguide changes when the optical surface tilts.

If at least one of the waveguides is arranged in a strain-neutral plane of the spring element and if, further, at least one of the waveguides is arranged in or on the spring element in such a way that the length of the waveguide changes when the optical surface tilts, then a strain on a waveguide caused by the tilt of the optical surface can be distinguished from a strain which has a different cause, for example a change in temperature. Both waveguides are affected by strain in the case of a thermal expansion but the waveguide arranged in the strain-neutral plane is not affected by strain and hence not affected by a change in length in the case of a tilt. Accordingly, it is possible hereby to distinguish between path length changes based on a tilt of the optical surface and path length changes that have a different cause.

Provision can be made for at least two waveguides to be present and arranged lying in different planes of the spring element in each case, with different strains arising in the different planes when the optical surface tilts.

With knowledge of the precise location of the planes and the expected strain on the different planes for a given tilt of the optical surface, it is likewise possible by way of an analysis of measurement beams propagating in the different planes to distinguish between path length changes based on a tilt of the optical surface and path length changes which have a different cause.

In a development of the optical apparatus according to the disclosure, provision can be made for the path length measuring device to comprise a power splitter which is configured and arranged to split the measurement radiation into at least two measurement beams and input couple the measurement beams into a respective waveguide forming a measurement section, with the path length measuring device comprising a power combiner which is configured and arranged to recombine the measurement beams following their propagation through the respective waveguides, with the measuring device being configured to sense the superimposed measurement beams.

Provision can be made for the measurement sections to each form arms of a Mach-Zehnder interferometer.

Optionally, the arms of the Mach-Zehnder interferometer are formed in the element connected to the optical element, for example in the spring element.

Provision can be made for one of the arms to form a measurement arm and another of the arms to form a reference arm of the Mach-Zehnder interferometer.

In this case, provision can be made for the measurement arm to experience a change in length in the case of a deformation of the optical element or connected element, for example of the spring element, while the reference arm is not influenced or only influenced slightly by the deformation.

A possible change in length of the measurement arm, and hence the actual tilt, can then be ascertained from an interferometric comparison of the optical path lengths of the measurement arm and reference arm between a situation in which there is a deformation of the connected element, for example the spring element, and a situation in which there is no deformation of the connected element, for example the spring element.

If the separation and superposition of the respective measurement beams is brought about by a power splitter and a power combiner, respectively, then this means that the power splitter and/or the power combiner, as monolithically integrated components, can be embodied as a part of the optical apparatus.

Further, it is possible to resort to proven technologies when selecting a suitable power splitter and/or a suitable power combiner.

In an alternative to that or in addition, provision can be made for the waveguide to be integrated in the spring element and be formed as a resonant structure, for example as a ring resonator and/or a racetrack resonator. In this case, the path length change induced by the deformation of the spring element allows an observation of a shift in the resonant frequency of the resonant structure.

In an alternative to that or in addition, provision can be made for the Mach-Zehnder interferometer to be realized with a two-by-two coupler, for example a 2×2 multimode interferometer (MMI), and two photodetectors. This means that an entire power of the measurement beams can always be detected.

In an alternative to that or in addition, provision can be made for the Mach-Zehnder interferometer to comprise a two-by-three coupler, for example a 2×3 multimode interferometer, and three photodetectors. This can ensure a high accuracy over an entire measurement region.

In an alternative to that or in addition, provision can be made for a static reference arm of the Mach-Zehnder interferometer to likewise be accommodated in the flexible spring element. This allows a differential measurement.

In a development of the optical apparatus according to the disclosure, provision can be made for the at least one waveguide to be arranged and configured such that as a result of a tilt of the optical surface the waveguide approaches or retreats from a reference region situated in the direct vicinity of the waveguide, in such a way that the reference region influences an evanescent field emerging from the waveguide, and the measuring device is configured to measure the influence.

If measuring the actual tilt is reduced to measuring the influence of the reference region on the evanescent field emanating from the waveguide then it is possible to realize a relatively precise measurement of the actual tilt since evanescent fields of light waves and light waveguides may have very small penetration depths and hence a significant position sensitivity.

In a development of the optical apparatus according to the disclosure, provision can be made for the measuring device to be configured to ascertain the actual tilt of the waveguide from an interference pattern of the measurement beam and/or ascertain the actual tilt of the waveguide from a measurement beam transmittance.

Using an interference pattern to sense the actual tilt of the waveguide can be desirable, especially when a fiber Bragg grating is used. The actual tilt of the optical surface can be deduced from the actual tilt of the waveguide.

Further, an actual tilt of the waveguide can also be ascertained from a transmittance of the measurement beam and/or measurement radiation. Determining the transmittance of the measurement beam and/or measurement radiation can be desirable, especially when evanescent fields are used and the actual tilt is measured.

Provision can be made for the waveguide to be in the form of an integrated waveguide, with it being possible to modify a mode index of the waveguide on account of the evanescent field when changing a refractive index distribution in a direct vicinity of the waveguide core. In this case, the waveguide can be part of an interferometric and/or resonant structure which is configured to measure refractive index changes by sensing interference phenomena or resonance shifts. In an alternative to that or in addition, a changeable transmission can be evaluated. As a result, the refractive index distribution in the immediate vicinity of the waveguide core is influenced for example by a distance from the reference region.

Provision can be made for the waveguide to be formed in or on a substrate plane, i.e. on a substrate carrying the spring element, and hence in stationary fashion and integrated in the substrate plane. For example, to this end provision can be made for elements mechanically coupled to the optical surface to be arranged placed tightly and/or next to the waveguide. In this context, these elements may serve as a reference region. Here, a change in the tilt of the optical surface may lead to a change in the distance of the elements from the waveguide. This can induce the above-described change in the mode index.

Provision can be made for a plurality of waveguides to be arranged with in each case different distances from the reference region. For example, the formation of a plurality of reference regions might also be provided.

In a development of the optical apparatus according to the disclosure, provision can be made for the at least one waveguide to be arranged on the optical element and/or for the at least one waveguide to be arranged on the connected element, for example the spring element, and for the at least one reference region to be stationary.

A configuration of the optical apparatus according to which the at least one waveguide is arranged on the optical element while the at least one reference region is stationary means that the waveguide can be formed as part of the optical element. The same applies if the at least one waveguide is arranged on the connected element, for example the spring element. On account of the tight mechanical coupling between the optical surface and the waveguide obtained thereby, the latter can reproduce the movements of the optical element at least indirectly, and a high measurement precision can be obtained. A stationary embodiment of the reference region means that the reference region can be arranged on base structures of the optical apparatus, for example.

In a development of the optical apparatus according to the disclosure, provision can be made for the at least one reference region to be arranged on the optical element and/or for the at least one reference region to be arranged on the connected element, for example the spring element, and for the at least one waveguide to be arranged stationarily.

A configuration of the arrangement of the reference region and the at least one waveguide which is inverted in comparison with the configuration described above means that a possibly less complex reference region is arranged on the movable spring element and/or the movable optical element, while a waveguide which potentially should have a more complex form can be arranged and embodied on a stationary base region. This can have desirable features, especially in the case of a monolithic design of the optical apparatus as a microsystem.

In a development of the optical apparatus according to the disclosure, provision can be made for the measuring device to comprise at least two waveguides which each form a closed measurement section, with the measurement sections being arranged such that an actual tilt of the optical surface about a first axis is able to be sensed via a first measurement section and an actual tilt of the optical surface about a second axis running orthogonal to the first axis is able to be sensed via a second measurement section.

If the measuring device is configured via at least two waveguides such that tilts of the optical surface about at least two axes can be sensed, then the optical apparatus can be used for example to measure tilts of optical surfaces mounted on Cardan-type joints.

To allow the micromirror to tilt, it can be desirable if the latter is coupled to movable elements, for example spring elements. An array of micromirrors intended to achieve a relatively large fill factor for use in lithographic optical systems can be provided, especially in an embodiment as a facet mirror, which will be described below. To this end, provision can be made for the spring elements to optionally be arranged below the micromirror, i.e. on the side of the optical element distant from the optical surface. To allow the micromirror to tilt about two axes, it is possible to provide and appropriately arrange spring elements for each of the two tilt axes. For example, four spring elements which form a Cardan-type joint may be provided. In this case, two of the spring elements can allow the mirror to tilt about an X-axis, and the other two spring elements can allow a tilt about a Y-axis running perpendicular to the X-axis.

For example, the micromirror might be tilted by way of actuators in the form of piezo layers applied to the spring elements. An additional or alternative tilt option consists in an integration of a capacitive actuator consisting of electrodes which are formed in each case on an upper side of a substrate carrying the spring elements and the micromirror and on a lower side of the micromirror.

Provision can be made for the two axes to run below the optical surface in a plane-parallel plane spaced apart from the rest position of the optical surface, for example in a plane of the at least one spring element.

Provision can also be made for the two axes to run on the optical surface. During tilting, this can prevent the optical surface from pivoting about a point or axis located away from the optical surface, which might be compensated for by a translational movement of the optical surface.

In a development of the optical apparatus according to the disclosure, provision can be made for a closed-loop control device with a control loop, optionally a closed-loop control circuit, to be provided for the purpose of setting a target tilt of the optical surface via the at least one actuator, with an actual tilt of the optical surface ascertained by the measuring device being taken into account.

Using the information obtained by measuring the actual tilt for the purpose of closed-loop control of the tilt of the optical surface to a specified target tilt allows precise open-loop and closed-loop control of the actual tilt, and hence of the effect of the optical surface on an incident radiation.

For example, it can be desirable if the information with regards to the actual tilt obtained thus can be included in a control of the at least one actuator.

Accordingly, the realization of a controlled system by the closed-loop control device can be provided for the purpose of setting an accurate tilt angle of the optical surface, with the actual tilt being provided for sensing the momentary tilt position, i.e. the actual tilt.

In the optical apparatus according to the disclosure, the actual tilt measurement is based on the influence on the measurement beam in the closed measurement section, while capacitive and/or piezoresistive sensors are used according to the prior art.

The piezoresistive sensors known from the prior art are temperature-sensitive per se, and hence susceptible to large temperature fluctuations. The prior art has disclosed complicated temperature correction methods for compensating temperature errors, and these involve additional temperature sensors and a complicated calibration. A plasma environment prevalent in an EUV projection exposure apparatus can further interfere with capacitive sensors, and these are moreover limited in terms of their sensitivity and hence their fields of use due to a limited installation space in the optical apparatus. This can be avoided by the optical apparatus according to the disclosure and some of its configuration options.

In a development of the optical apparatus according to the disclosure, provision can be made for the closed-loop control device to be configured to correct at least one temperature-induced and/or strain-induced deviation of an actual tilt from a target tilt of the optical surface.

For example, the actual tilt might deviate from a target tilt due to temperature changes or strains. If the closed-loop control device is configured to correct such deviations, then this enables an even more precise effect of the optical surface on an incident radiation as the latter can be exactly aligned, even over relatively long periods of time.

As a result, the optical apparatus counteracts drift movements and fluctuations and thus enables a long-term stability of the effect of the optical element. Especially when used in projection exposure apparatuses, such a long-term stability may allow an increased throughput with unchanged high precision, and this may lead to desirable commercial features.

For temperature compensation purposes, provision can be made for the measuring device to comprise a symmetrically embodied measurement section constructed as a Mach-Zehnder interferometer.

In an alternative to that or in addition, asymmetric Mach-Zehnder interferometers may be combined with reference Mach-Zehnder interferometers in order to enable temperature-independent measurements. Further, alternative interferometric structures, Michelson interferometers for example, may be provided as measurement sections.

Provision can be made for the temperature of the optical element and/or optical surface to be measurable via a ring resonator which is integrated in the optical element, especially in the vicinity of the optical surface. This also renders a direct measurement of the EUV radiation power absorbed by the optical surface ascertainable.

In a development of the optical apparatus according to the disclosure, provision can be made for a plurality of optical elements to be provided and for the optical elements to be formed as micromirrors.

If the optical elements are all in the form of micromirrors, then these profit to an extent from a highly precise measurement of the actual tilt. Further, the micromirrors can be formed as part of a facet mirror described below, for example a field facet mirror and/or pupil facet mirror of a projection exposure apparatus. In this case, provision can be made for a respective optical surface of an optical element to form a facet of the facet mirror.

In a development of the optical apparatus according to the disclosure, provision can be made for the optical apparatus to be in the form of a field facet mirror and/or pupil facet mirror, which comprises a plurality of optical elements in the form of micromirrors, with the optical surfaces being formed as reflective planes, each of which being tiltable about two mutually orthogonal axes.

If an overall surface is formed by a multiplicity of optionally independent surfaces, then an accurate knowledge of the actual tilt can help for the purpose of precisely controlling the shape of the overall surface.

In illumination systems of EUV lithography systems for example, individual field facets of the field facet mirror can be assigned to differently positioned pupil facets of a pupil facet mirror. An increasingly finer segmentation of the field facets can be provided for the purpose of improving imaging properties of the illumination system, with the individual segments being able to be realized by micromirrors which in turn can be tilted on an individual basis.

In this case, it can be desirable if the micromirrors are tiltable about two axes and are able at the same time to dissipate the high thermal loads arising due to the EUV radiation, which represents the projection radiation in an EUV lithography system.

If the optical apparatus is embodied as field facet mirror and/or as pupil facet mirror which comprises a plurality of optical elements, and if the optical surfaces are embodied as mirror planes which are each tiltable about two axes, then devices of the optical apparatus can be used to measure and control a multiplicity of optical elements. For example, a single radiation source of the optical apparatus can be provided to supply a multiplicity of measurement sections in a multiplicity of optical elements. Costs can be saved accordingly as a result.

To achieve the highest possible fill factor for the facets of the field facet mirror and/or pupil facet mirror which are optionally embodied as micromirrors, provision can be made for the entire actuator system and sensor system and for further mechanical elements, for example the at least one actuator, the measuring device and the spring element, to be arranged below the optical surface, optionally on the lower side of the optical element.

The above-described embodiments of the optical apparatus according to the disclosure enable a relatively high positioning accuracy for the optical surface and, connected therewith, a low sensitivity of the alignment of the optical surface to disturbances, for example temperature fluctuations.

The above-described optical apparatus and its embodiments mean that the utilized optical sensor system can be embodied robustly vis-à-vis electromagnetic radiation and less space is used in comparison with state-of-the-art interdigital electrodes for capacitive measurements. Further, there is the feature of multi-sensor fusion due to a platform character of the photonic integrated circuit technology (PIC technology). The use of interference phenomena or resonance phenomena in optical sensor systems allows the implementation of a sensitive measurement method caused by the lever action of the interference phenomena or resonance phenomena.

The disclosure also relates to a method for measuring an actual tilt of an optical surface.

In the method according to the disclosure for measuring an actual tilt of an optical surface of an optical element, for example of a lithography system, the actual tilt of the optical surface is determined by at least one measurement beam which propagates along a measurement section, with one or more actuators being arranged to influence the tilt of the optical surface. According to the disclosure, provision is made for a closed measurement section to be formed by at least one waveguide, with a measurement beam being input coupled into the waveguide such that one or more modes of the measurement beam propagate through the waveguide. In this case, the waveguide is arranged such that the measurement beam propagating through the waveguide is influenced by a tilt of the optical surface, with the influence on the measurement beam caused by the tilt of the surface being sensed and the actual tilt of the surface being determined therefrom.

The method according to the disclosure means that a success of an effect of the at least one actuator on the optical surface can be verified directly by virtue of ascertaining a mechanical effect, i.e. the actual tilt of the optical surface.

In this way, it is possible to obtain an accurate prediction, as the latter is based on empirical measurements, of the true actual tilt of the optical surface after the effect of the at least one actuator has been set.

Further, the information captured by the method according to the disclosure allows accurate monitoring of the effect of the optical surface on a radiation incident on the optical surface. For example, a beam deflection can be predicted precisely.

The use of optical metrology, embodied by the waveguide and the measurement beam propagating in the waveguide, further allows contactless sensing of the actual tilt. This can increase the stability of the optical apparatus or of the alignment of the optical surface.

In order to set a target tilt, provision can be made for the optical surface to be tilted by up to 30°, for example by 3° to 30°, vis-à-vis a rest position via the at least one actuator.

In a development of the method according to the disclosure, provision can be made for the at least one actuator to be formed by a microelectromechanical system, and/or for the at least one optical element to be formed by a micromirror.

An embodiment of the actuator and/or at least one optical element as a microsystem means that these profit to an extent from a highly precise measurement of the actual tilt.

A deflection of the optical surface by a few nanometers in the case of a micromirror may already lead to a relevant tilt. To be able to measure deflections of the order of a few nanometers with high precision, the method according to the disclosure offers an option by way of a contactless optical measurement.

In a development of the method according to the disclosure, provision can be made for a change in length of the measurement section provided by the waveguide to be sensed, and for the actual tilt of the optical surface to be determined from the change in length.

If the measurement of the actual tilt can be reduced to a measurement of a change in length of the measurement section, then it is possible to resort to distance measurement methods which may represent a reliable and precise alternative to the method of a direct angle measurement.

Provision can be made for the measurement sections to each be formed by arms of a Mach-Zehnder interferometer.

Optionally, the arms of the Mach-Zehnder interferometer are formed in the element connected to the optical element, for example in the spring element.

Provision can be made for a measurement arm to be formed by one of the arms and for a reference arm of the Mach-Zehnder interferometer to be formed by another of the arms.

As a result of the measurement arm length in the Mach-Zehnder interferometer being dependent on an angle of the actual tilt of the optical surface, a tilt angle-dependent relative phase angle of two measurement beams is effected during the recombination by a power combiner. As a result of the two measurement beams being made to interfere, this yields a tilt angle-dependent intensity or intensity pattern which is measured via the photodetector, for example a CCD camera, and consequently represents an evaluable measurement signal.

In a development of the method according to the disclosure, provision can be made for a path length difference, caused by the actual tilt of the optical surface, of the measurement beam propagating through the waveguide to be measured; for example, an interference pattern, such as a measurement spectrum, of the measurement beam is ascertained.

If a change in length of the measurement section for example can be reduced to a change in the optical path length of the measurement beam in the measurement section, then it is possible to resort to a measurement of interference patterns and/or measurement spectra of the measurement beam. If the path length difference is functionally caused by the actual tilt of the optical surface, then an analysis of the interference pattern and/or measurement spectrum allows a precise determination of the actual tilt.

In other words, a path length difference of the measurement beam is caused by the actual tilt, and an interference pattern, for example a measurement spectrum of the measurement beam, which is analyzed is caused by the path length difference of the measurement beam. In this case, the actual tilt is deduced on the basis of the analysis of the interference pattern, for example the measurement spectrum, while taking account of the functional relationships between tilt, path length difference and interference pattern, for example measurement spectrum.

In a development of the method according to the disclosure, provision can be made for a change in length of the waveguide to be determined from a phase of the measurement beam.

If the change in length of the waveguide is determined from the phase of the measurement beam, then the measurement of the change in length can in turn be reduced to an interference phenomenon, and this allows a precise measurement of the change in length.

In a development of the method according to the disclosure, provision can be made for the respective actual tilt to be determined from the change in length of a plurality of waveguides at different depths in a spring element which holds the optical surface.

If the respective actual tilt is determined from the change in length of a plurality of waveguides at different depths in the spring element, then the strains of the spring element at the different depths and hence its deflection can be deduced from a comparison of the changes in lengths at the different depths of the spring element. In turn, the actual tilt of the optical surface held by the spring element can be deduced from the deflection of the spring element.

The spring element represents the component part of the optical apparatus with the greatest deformation. If the measurement section is integrated directly in or on the spring element, then it is possible to obtain a relatively strong signal and provide direct feedback for a spring element control.

Provision can be made for empirical calibration curves to be sensed for the purpose of determining the actual tilt from a measured interference pattern of the measurement beams, and for a value of the actual tilt to be deduced directly from an observed interference pattern on the basis of the calibration curves.

In a development of the method according to the disclosure, provision can be made for at least one of the waveguides to be arranged in a strain-neutral plane of the spring element and at least one of the waveguides to be arranged in or on the spring element such that the length of the waveguide changes when the optical surface tilts, especially when an envisaged tilt (target tilt) is set.

The arrangement of at least one of the waveguides in the strain-neutral plane of the spring element enables the separation of those strains of the spring element which lead to a tilt of the optical surface from those strains of the spring element which can be traced back to other causes. For example, a temperature-related strain of the spring element affects the strain-neutral plane of the spring element to the same extent as the other planes of the spring element. However, a deflection of the spring element does not cause any strain in the strain-neutral plane. Accordingly, non-deflecting effects can be separated by way of a comparison of the strains in the different planes.

Provision can be made for all waveguides to be arranged in a single or common plane, with only a region in which the waveguide forming the measurement arm is arranged bending significantly and for example being a flexible region of the spring element. A region of the waveguide forming the reference arm can be arranged such that it experiences no bending or such that it is a rigid region of the optical element for example.

In a development of the method according to the disclosure, provision can be made for a measurement radiation to be split into at least two measurement beams and the measurement beams to each be coupled into a waveguide which forms a measurement section, with the measurement beams being recombined following their propagation through the respective waveguides and the superimposed measurement beams, for example the power of the superimposed measurement beams, being sensed, for example detected by a photodetector, in order to determine an actual tilt of the optical surface therefrom.

A split of the measurement radiation into at least two measurement beams which, following a respective propagation through the measurement section respectively assigned thereto, are combined and superimposed enables the direct formation of interference phenomena which are caused by different path length changes of the various parameters of the measurement radiation or the various measurement beams. In this case, the change in the interference phenomena observed thus may allow conclusions to be drawn about the actually adopted actual tilt.

A photodetector is suitable for a real-time detection of interference patterns, which appear as intensity patterns, in a simple and cost-effective manner.

Provision can be made for devices for sensing the measurement beams, for example photodetectors, to be replaced by output coupling elements and for the measurement beam to be input coupled into an optical waveguide, such as an optical fiber. Then, the measurement beam is detected using a radiation measuring device, for example a photodiode and/or a CCD camera, which is spatially separated from the measurement section.

Provision can be made for a multiplexing device which is configured for spectral and/or temporal multiplexing in order to enable a readout of a plurality of measurement sections, such as more than 100 measurement sections, by way of a single optical waveguide and/or by way of a single photodiode.

Provision can be made for
a first measurement beam in a first measurement section to be guided through a region which is deformed when the optical surface tilts, for example guided through a flexible region of the spring element, with
a second measurement beam in a second measurement section being guided through a region which is deformed differently to the first region or not deformed when the optical surface is tilted,
with the measurement beams optionally being guided within a common plane.

Using this as a starting point, the development described below represents a special case.

In a development of the method according to the disclosure, provision can be made for
a first measurement beam in a first measurement section to be guided through a region which is deformed when the optical surface tilts, for example guided through a flexible region of the spring element, with
a second measurement beam in a second measurement section being guided through a region which remains stiff or is not deformed when the optical surface tilts, for example guided through a stiff region of the optical element, with
the measurement beams optionally being guided within a common plane.

For example, a degree of deformation of the deformable region can be determined by way of a superposition of the measurement beams propagating in the respective waveguides since only one of the two waveguides is affected by the deformation and therefore experiences e.g. a change in length. Accordingly, an interference pattern of the measurement beams from the respective waveguides changes with the degree of deformation of the deformable region.

In a development of the method according to the disclosure, provision can be made for the at least one waveguide to be arranged and configured such that as a result of a tilt of the optical surface the waveguide is made to approach or retreat from a reference region situated in the direct vicinity of the waveguide, in such a way that the reference region influences an evanescent field emerging from the waveguide, and the influence is measured and the actual tilt of the optical surface is determined therefrom.

The use of evanescent fields for measuring the actual tilt means that interactions between the reference region and the evanescent field depend very strongly on distance. As a result, distances between the waveguide and the reference region can be determined on very small scales, for example in the nanometer range. This allows a highly precise determination of the actual tilt, especially when the optical element is in the form of a micromirror.

In a development of the method according to the disclosure, provision can be made for the actual tilt of the optical surface vis-à-vis the reference region to be ascertained from an interference pattern of the measurement beams, and/or for the actual tilt of the optical surface to be ascertained from a transmission of the measurement beam.

An interference pattern and/or a transmission of the measurement radiation can be used as a readout signal, especially when evanescent fields are used. Such signals can be analyzed and evaluated in known and reliable fashion.

An embodiment of the method may comprise one or more of the following steps:
the coherent measurement radiation is input coupled into a feeding waveguide from an integrated radiation source or an external radiation source;
a power splitter is used to divide the light into at least two closed measurement sections, which are each formed by a waveguide, with the two measurement sections being formed as two arms of a Mach-Zehnder interferometer;
the measurement beam in each case propagates through the arm realized by the waveguide and accumulates a phase in the process, the latter being determined according to the product of a free space propagation constant, an effective mode index and a physical length of the waveguide;
the measurement beams from the two arms of the Mach-Zehnder interferometer are combined again into a single waveguide by a power combiner;
the power of the superimposed signal is detected via a photodetector.

The disclosure also relates to a lithography system.

The lithography system according to the disclosure, for example a projection exposure apparatus for semiconductor lithography, comprises an illumination system with a radiation source and an optical unit which comprises at least one optical element. According to the disclosure, provision is made for
at least one optical apparatus according to the disclosure to be provided, with at least one of the optical elements being an optical element of the at least one optical apparatus according to the disclosure, and/or
at least one of the optical elements comprises an optical surface, the actual tilt of which is ascertained using a method according to the disclosure.

The lithography system according to the disclosure enables a reliable and precise operation as a result of the accurate measurement or monitoring of the alignment of the individual optical surfaces of the optical elements.

An operation of the lithography system with a high long-term stability and hence a high throughput is enabled, especially when feeding the information obtained by measuring the actual tilt into at least one control loop which controls the actuators for aligning or tilting the optical surface.

To solve the object on which the disclosure is based, provision can be made for optical sensors which, in full or in part, are integrated in or on a movable element of the micromirror, are in contact with the latter and/or are arranged between the connected element of the micromirror and an underlying substrate or a base region. The optical sensor, which may be part of the measuring device, is configured to make the measurement beam interfere optically. In this case, the actual tilt of the micromirror is realized by a measurement of the translation or the deformation of the micromirror itself or of a movable element connected to the micromirror, using the principle of optical interference as a basis.

Features described in conjunction with one of the subjects of the disclosure, specifically given by the optical apparatus according to the disclosure, the method according to the disclosure, or the lithography system according to the disclosure, are also implementable for the other subjects of the disclosure. Likewise, features specified in conjunction with one of the subjects of the disclosure can also be understood in relation to the other subjects of the disclosure.

Additionally, it should be noted that terms such as “comprising”, “having”, or “with” do not exclude other features or steps. Furthermore, terms such as “a (n)” or “the” which indicate single steps or features do not exclude a plurality of features or steps—and vice versa.

However, in a puristic embodiment of the disclosure, provision may also be made for the features introduced in the disclosure using the terms “comprising”, “having”, or “with” to be an exhaustive enumeration. Accordingly, one or more enumerations of features can be considered to be exhaustive within the scope of the disclosure, for example respectively considered for each claim. For example, the disclosure can consist exclusively of the features specified in any of the claims.

It should be noted that labels such as “first” or “second”, etc. are used predominantly for reasons of distinguishability between respective apparatus or method features and are not necessarily intended to indicate that features involve one another or are related to one another.

Exemplary embodiments of the disclosure will be described in detail hereinbelow with reference to the drawing.

The figures each show preferred exemplary embodiments in which individual features of the present disclosure are illustrated in combination with one another. Features of an exemplary embodiment are also implementable independently of the other features of the same exemplary embodiment, and may readily be combined accordingly by a person skilled in the art to form further viable combinations and sub-combinations with features of other exemplary embodiments.

### BRIEF DESCRIPTION OF THE DRAWINGS

In the drawing:

FIG. 1 shows a meridional section of an EUV projection exposure apparatus;

FIG. 2 shows a DUV projection exposure apparatus;

FIG. 3 shows a schematic illustration of a possible embodiment of an optical apparatus according to the disclosure;

FIG. 4 shows a schematic illustration of a possible embodiment of an optical apparatus according to the disclosure as field facet mirror;

FIG. 5 shows a schematic illustration of a section through a part of a further possible embodiment of an optical apparatus;

FIG. 6 shows a schematic illustration of a part of the embodiment of an optical apparatus according to FIG. 5 in an upwardly deflected state;

FIG. 7 shows a schematic illustration of a part of the embodiment of an optical apparatus according to FIG. 5 in a downwardly deflected state;

FIG. 8 shows a schematic illustration of a plan view of a part of the embodiment of the optical apparatus according to FIG. 5;

FIG. 9 shows a schematic illustration of a part of a further possible embodiment of an optical apparatus according to the disclosure;

FIG. 10 shows a schematic illustration of a modification of the embodiment according to FIG. 9;

FIG. 11 shows a schematic illustration of a part of a further possible embodiment of an optical apparatus according to the disclosure;

FIG. 12 shows a schematic illustration of an enlarged detail from FIG. 11;

FIG. 13 shows a block diagram-type illustration of a method according to the disclosure;

FIG. 14 shows a schematic illustration of a further possible embodiment of an optical apparatus according to the disclosure; and

FIG. 15 shows a schematic illustration of a possible arrangement of two measurement sections.

### DETAILED DESCRIPTION

In the figures, functionally identical elements are given the same reference signs.

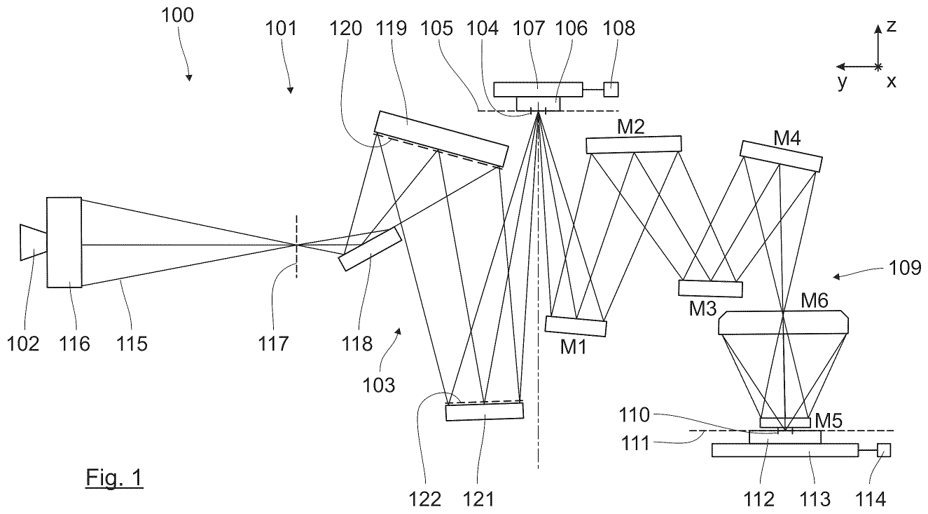

With reference to FIG. 1, certain components of a microlithographic EUV projection exposure apparatus 100 as an example of a lithography system are initially described below in exemplary fashion. The description of the basic structure of the EUV projection exposure apparatus 100 and of the component parts thereof should not be interpreted restrictively here.

An illumination system 101 of the EUV projection exposure apparatus 100 comprises, besides a radiation source 102, an illumination optical unit 103 for the illumination of an object field 104 in an object plane 105. What is exposed here is a reticle 106 arranged in the object field 104. The reticle 106 is held by a reticle holder 107. The reticle holder 107 is displaceable, for example in a scanning direction, by way of a reticle displacement drive 108.

In FIG. 1, a Cartesian xyz-coordinate system is plotted to aid the explanation. The x-direction runs perpendicularly into the plane of the drawing. The y-direction runs horizontally, and the z-direction runs vertically. In FIG. 1, the scanning direction runs in the y-direction. The z-direction runs perpendicular to the object plane 105.

The EUV projection exposure apparatus 100 comprises a projection optical unit 109. The projection optical unit 109 serves for imaging the object field 104 into an image field 110 in an image plane 111. The image plane 111 extends parallel to the object plane 105. Alternatively, an angle that differs from 0° between the object plane 105 and the image plane 111 is also possible.

A structure on the reticle 106 is imaged on a light-sensitive layer of a wafer 112 arranged in the region of the image field 110 in the image plane 111. The wafer 112 is held by a wafer holder 113. The wafer holder 113 is displaceable by way of a wafer displacement drive 114, for example in the y-direction. The displacement, firstly, of the reticle 106 by way of the reticle displacement drive 108 and, secondly, of the wafer 112 by way of the wafer displacement drive 114 can be synchronized with one another.

The radiation source 102 is an EUV radiation source. The radiation source 102 emits EUV radiation 115, for example, which is also referred to as used radiation or illumination radiation below. For example, the used radiation 115 has a wavelength in the range between 5 nm and 30 nm. The radiation source 102 can be a plasma source, for example an LPP source (“laser produced plasma”) or a GDPP source (“gas discharged produced plasma”). It can also be a synchrotron-based radiation source. The radiation source 102 can be a free electron laser (FEL).

The illumination radiation 115 emanating from the radiation source 102 is focused by a collector 116. The collector 116 can be a collector with one or more ellipsoidal and/or hyperboloidal reflection surfaces. The at least one reflection surface of the collector 116 can be impinged upon by the illumination radiation 115 with grazing incidence (GI), i.e. with angles of incidence greater than 45°, or with normal incidence (NI), i.e. with angles of incidence less than 45°. The collector 116 can be structured and/or coated, firstly, for optimizing its reflectivity for the used radiation 115 and, secondly, for suppressing extraneous light.

Downstream of the collector 116, the illumination radiation 115 propagates through an intermediate focus in an intermediate focal plane 117. The intermediate focal plane 117 may represent a separation between a radiation source module, comprising the radiation source 102 and the collector 116, and the illumination optical unit 103.

The illumination optical unit 103 comprises a deflection mirror 118 and, downstream thereof in the beam path, a first facet mirror 119. The deflection mirror 118 may be a plane deflection mirror or, alternatively, a mirror with a beam-influencing effect going beyond the pure deflection effect. In an alternative to that or in addition, the deflection mirror 118 may be designed as a spectral filter that separates a used light wavelength of the illumination radiation 115 from extraneous light at a different wavelength. If the first facet mirror 119 is arranged in a plane of the illumination optical unit 103 that is optically conjugate to the object plane 105 as a field plane, it is also referred to as a field facet mirror. The first facet mirror 119 comprises a plurality of individual first facets 120, which are also referred to below as field facets. Only a few of these facets 120 are illustrated in FIG. 1 by way of example.

The first facets 120 can be embodied in the form of macroscopic facets, for example in the form of rectangular facets or in the form of facets with an arcuate peripheral contour or a peripheral contour of part of a circle. The first facets 120 may be embodied as plane facets or alternatively as convexly or concavely curved facets.

As is known for example from DE 10 2008 009 600 A1, the first facets 120 themselves can also each be composed of a multiplicity of individual mirrors, for example a multiplicity of micromirrors. For example, the first facet mirror 119 can be in the form of a microelectromechanical system (MEMS system). For details, reference is made to DE 10 2008 009 600 A1.

The illumination radiation 115 travels horizontally, i.e., in the y-direction, between the collector 116 and the deflection mirror 118.

In the beam path of the illumination optical unit 103, a second facet mirror 121 is disposed downstream of the first facet mirror 119. Provided the second facet mirror 121 is arranged in a pupil plane of the illumination optical unit 103, it is also referred to as a pupil facet mirror. The second facet mirror 121 can also be arranged at a distance from a pupil plane of the illumination optical unit 103. In this case, the combination of the first facet mirror 119 and the second facet mirror 121 is also referred to as a specular reflector. Specular reflectors are known from US 2006/0132747 A1, EP 1 614 008 B1, and U.S. Pat. No. 6,573,978.

The second facet mirror 121 comprises a plurality of second facets 122. In the case of a pupil facet mirror, the second facets 122 are also referred to as pupil facets.

The second facets 122 may likewise be macroscopic facets, which may for example have a round, rectangular or else hexagonal periphery, or may alternatively be facets composed of micromirrors. In this regard, reference is likewise made to DE 10 2008 009 600 A1.

The second facets 122 can have plane or, alternatively, convexly or concavely curved reflection surfaces.

The illumination optical unit 103 consequently forms a doubly faceted system. This basic principle is also referred to as fly's eye integrator.

It may be desirable to arrange the second facet mirror 121 not exactly in a plane that is optically conjugate to a pupil plane of the projection optical unit 109.

With the aid of the second facet mirror 121, the individual first facets 120 are imaged into the object field 104. The second facet mirror 121 is the last beam-shaping mirror or else indeed the last mirror for the illumination radiation 115 in the beam path upstream of the object field 104.

In a further embodiment (not illustrated) of the illumination optical unit 103, a transfer optical unit may be arranged in the beam path between the second facet mirror 121 and the object field 104, and contributes for example to the imaging of the first facets 120 into the object field 104. The transfer optical unit may have exactly one mirror or, alternatively, also two or more mirrors, which are arranged in succession in the beam path of the illumination optical unit 103. For example, the transfer optical unit can comprise one or two mirrors for normal incidence (NI mirror, “normal incidence” mirror) and/or one or two mirrors for grazing incidence (GI mirror, “grazing incidence” mirror).

In the embodiment shown in FIG. 1, the illumination optical unit 103 comprises exactly three mirrors downstream of the collector 116, specifically the deflection mirror 118, the field facet mirror 119 and the pupil facet mirror 121.

In a further embodiment of the illumination optical unit 103, the deflection mirror 118 can also be omitted, and so the illumination optical unit 103 can then have exactly two mirrors downstream of the collector 116, specifically the first facet mirror 119 and the second facet mirror 121.

The imaging of the first facets 120 into the object plane 105 via the second facets 122 or using the second facets 122 and a transfer optical unit is routinely only approximate imaging.

The projection optical unit 109 comprises a plurality of mirrors Mi, which are numbered in accordance with their arrangement in the beam path of the EUV projection exposure apparatus 100.

In the example illustrated in FIG. 1, the projection optical unit 109 comprises six mirrors M1 to M6. Alternatives with four, eight, ten, twelve or any other number of mirrors Mi are likewise possible. The penultimate mirror M5 and the last mirror M6 each have a passage opening for the illumination radiation 115. The projection optical unit 109 is a doubly obscured optical unit. The projection optical unit 109 has an image-side numerical aperture which is greater than 0.5 and which can also be greater than 0.6 and, for example, can be 0.7 or 0.75.

Reflection surfaces of the mirrors M1 can be in the form of free-form surfaces without an axis of rotational symmetry. Alternatively, the reflection surfaces of the mirrors M1 can be designed as aspherical surfaces with exactly one axis of rotational symmetry of the reflection surface shape. Just like the mirrors of the illumination optical unit 103, the mirrors M1 may comprise highly reflective coatings for the illumination radiation 115. These coatings may be in the form of multi-layer coatings, for example with alternating layers of molybdenum and silicon.

The projection optical unit 109 has a large object-image offset in the y-direction between a y-coordinate of a center of the object field 104 and a y-coordinate of the center of the image field 110. In the y-direction, this object-image offset can be of approximately the same magnitude as a z-distance between the object plane 105 and the image plane 111.

The projection optical unit 109 may for example have an anamorphic form. For example, it has different imaging scales βx, βy in the x- and y-directions. The two imaging scales βx, βy of the projection optical unit 109 can be (βx, βy)=(+/−0.25, +/−0.125). A positive imaging scale β means imaging without image inversion. A negative sign for the imaging scale β means imaging with image inversion.

The projection optical unit 109 consequently leads to a reduction in size with a ratio of 4:1 in the x-direction, i.e. in a direction perpendicular to the scanning direction.

The projection optical unit 109 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 104 and the image field 110 may be the same or may be different depending on the embodiment of the projection optical unit 109. Examples of projection optical units with different numbers of such intermediate images in the x- and y-directions are known from US 2018/0074303 A1.

One of the pupil facets 122 in each case is assigned to exactly one of the field facets 120, in each case to form an illumination channel for illuminating the object field 104. For example, this can produce illumination according to the Köhler principle. The far field is deconstructed into a multiplicity of object fields 104 using the field facets 120. The field facets 120 create a plurality of images of the intermediate focus on the pupil facets 122 respectively assigned thereto.

The field facets 120 are each imaged by an assigned pupil facet 122 onto the reticle 106 in a manner overlaid on one another in order to illuminate the object field 104. The illumination of the object field 104 is for example as homogeneous as possible. It can have a uniformity error of less than 2%. Field uniformity can be attained by overlaying different illumination channels.

The illumination of the entrance pupil of the projection optical unit 109 can be defined geometrically by way of an arrangement of the pupil facets. The intensity distribution in the entrance pupil of the projection optical unit 109 can be set by selecting the illumination channels, for example the subset of the pupil facets that guide light. This intensity distribution is also referred to as illumination setting.

A likewise preferred pupil uniformity in the region of portions of an illumination pupil of the illumination optical unit 103 that are illuminated in a defined way can be achieved by a redistribution of the illumination channels.

Further aspects and details of the illumination of the object field 104 and for example of the entrance pupil of the projection optical unit 109 are described below.

The projection optical unit 109 may have a homocentric entrance pupil for example. The latter can be accessible. It can also be inaccessible.

The entrance pupil of the projection optical unit 109 generally cannot be illuminated exactly via the pupil facet mirror 121. The aperture rays often do not intersect at a single point in the event of imaging by the projection optical unit 109, which telecentrically images the center of the pupil facet mirror 121 onto the wafer 112. However, it is possible to find an area in which the spacing of the aperture rays that is determined in pairs becomes minimal. This area represents the entrance pupil or an area in real space that is conjugate thereto. For example, this area has a finite curvature.

It may be the case that the projection optical unit 109 has different poses of the entrance pupil for the tangential beam path and for the sagittal beam path. In this case, an imaging element, for example an optical component part of the transfer optical unit, should be provided between the second facet mirror 121 and the reticle 106. With the aid of this optical component, it is possible to take account of the different pose of the tangential entrance pupil and the sagittal entrance pupil.

In the arrangement of the components of the illumination optical unit 103 illustrated in FIG. 1, the pupil facet mirror 121 is arranged in an area conjugate to the entrance pupil of the projection optical unit 109. The first field facet mirror 119 is arranged so as to be tilted in relation to the object plane 105. The first facet mirror 119 is arranged so as to be tilted in relation to an arrangement plane defined by the deflection mirror 118.

The first facet mirror 119 is arranged so as to be tilted in relation to an arrangement plane defined by the second facet mirror 121.

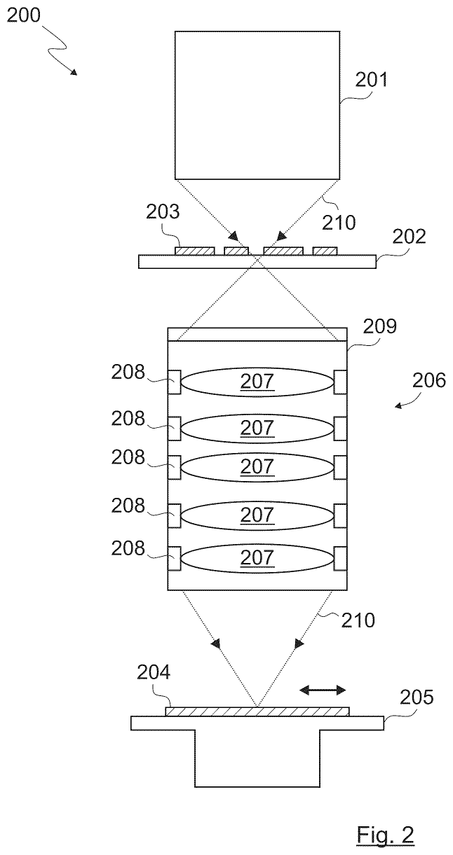

FIG. 2 shows an exemplary DUV projection exposure apparatus 200. The DUV projection exposure apparatus 200 comprises an illumination system 201, a device known as a reticle stage 202 for receiving and exactly positioning a reticle 203 by which the later structures on a wafer 204 are determined, a wafer holder 205 for holding, moving, and exactly positioning the wafer 204, and an imaging device, specifically a projection optical unit 206, with a plurality of optical elements, for example lens elements 207, which are held by way of mounts 208 in a lens housing 209 of the projection optical unit 206.

As an alternative or in addition to the lens elements 207 illustrated, provision can be made of various refractive, diffractive, and/or reflective optical elements, inter alia also mirrors, prisms, terminating plates, and the like.

The basic functional principle of the DUV projection exposure apparatus 200 makes provision for the structures introduced into the reticle 203 to be imaged onto the wafer 204.

The illumination system 201 provides a projection beam 210 in the form of electromagnetic radiation, which is used for the imaging of the reticle 203 onto the wafer 204. The source used for this radiation may be a laser, a plasma source, or the like. The radiation is shaped in the illumination system 201 via optical elements such that the projection beam 210 has the desired properties with regard to diameter, polarization, shape of the wavefront, and the like when it is incident on the reticle 203.

An image of the reticle 203 is created via the projection beam 210 and transferred from the projection optical unit 206 onto the wafer 204 in an appropriately reduced form. In this case, the reticle 203 and the wafer 204 can be moved synchronously, so that regions of the reticle 203 are imaged onto corresponding regions of the wafer 204 virtually continuously during what is called a scanning operation.

An air gap between the last lens element 207 and the wafer 204 can optionally be replaced by a liquid medium which has a refractive index of greater than 1.0. The liquid medium can be high-purity water, for example. Such a set-up is also referred to as immersion lithography and has an increased photolithographic resolution.

The use of the disclosure is not restricted to use in projection exposure apparatuses 100, 200, for example also not with the described set-up. The disclosure is suitable for any lithography system, but for example for projection exposure apparatuses having the described structure. The disclosure is also suitable for EUV projection exposure apparatuses which have a smaller image-side numerical aperture than those described in the context of FIG. 1. For example, the disclosure is also suitable for EUV projection exposure apparatuses which have an image-side numerical aperture from 0.25 to 0.5, such as 0.3 to 0.4, for example 0.33. The disclosure and the following exemplary embodiments should also not be understood as being restricted to a specific design. The figures that follow illustrate the disclosure merely by way of example and in highly schematized form.

FIG. 3 shows in perspective fashion a schematic illustration of a possible embodiment of an optical apparatus 1, for example for a lithography system. For example, the lithography system can be a projection exposure apparatus 100, 200 for semiconductor lithography. The optical apparatus 1 comprises at least one optical element 2 having at least one optical surface 3. Further, the optical apparatus 1 comprises an actuator 4, optionally a plurality of actuators, serving to tilt the optical surface 3 of the optical element 2. The optical apparatus 1 also comprises a measuring device 5 for sensing a tilt of the optical surface 3 from a rest position.

The measuring device 5 comprises at least one waveguide 6 which forms a closed measurement section 7, with the waveguide 6 being configured to input couple and allow propagation of one or more modes of a measurement beam 8.

The waveguide 6 is arranged such that a tilt of the optical surface 3 influences the measurement beam 8 propagating through the waveguide 6, with the measuring device 5 being configured to sense an influence on the measurement beam 8 caused by the tilt of the surface 3.

In the exemplary embodiment of the optical apparatus 1 depicted in FIG. 3, provision is optionally made for a radiation source 9 for forming a measurement radiation, optionally a coherent measurement radiation, which forms the measurement beam 8.

The radiation source 9 is part of the optical apparatus 1 in the exemplary embodiment. However, the measurement radiation can also be provided by an external radiation source 9.

In an alternative embodiment (not depicted here), provision can be made for the radiation source 9 to be formed in a manner integrated, optionally monolithically integrated, in the optical apparatus 1.

In the exemplary embodiment of the optical apparatus 1 depicted in FIG. 3, provision is optionally made for the waveguide 6 to be configured to allow propagation of one or more modes of a coherent measurement beam 8.

FIG. 3 shows an exemplary embodiment of the optical apparatus 1, in which, optionally, the at least one actuator 4 is in the form of a micromechanical system, and the at least one optical element 2 is in the form of a micromirror 2a.

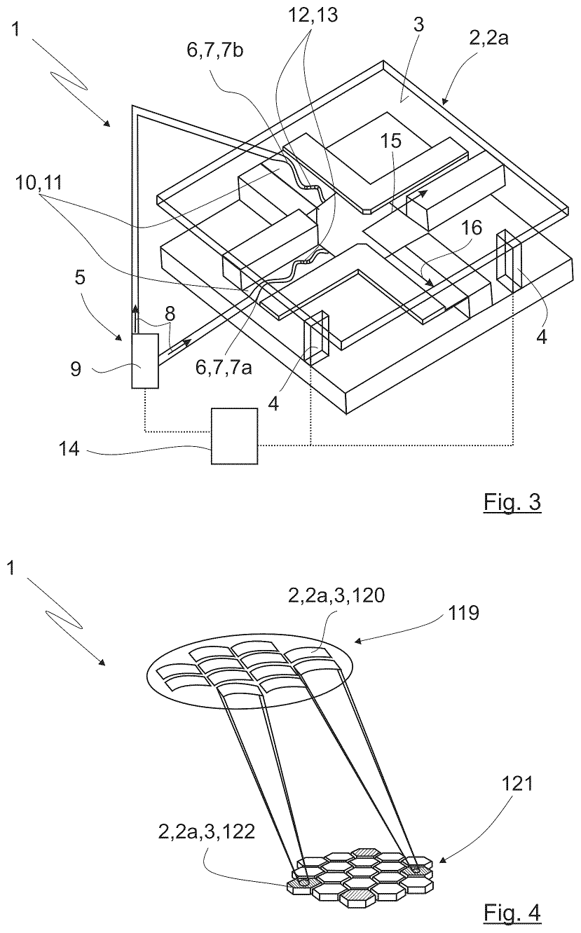

Optionally, embodiments (see FIG. 4) may be provided, in which the at least one optical element 2 is in the form of a micromirror 2a of a facet mirror, for example a field facet mirror or a pupil facet mirror, for example of the field facet mirror 119 or of the pupil facet mirror 121 in FIG. 1. In such an embodiment, provision is optionally made (albeit not depicted in FIG. 4) for the at least one actuator 4 to be in the form of a micromechanical system and the radiation source 9 (likewise not depicted in FIG. 4) to have a monolithically integrated form.

In FIG. 1, the micromirror 2a is provided with reference sign 120 or 122.

In alternative embodiments, provision can be made for only the at least one actuator 4 to be in the form of a micromechanical system and/or the at least one optical element 2 to be in the form of a micromirror 2a and/or the radiation source 9 to have a monolithically integrated form.

In the exemplary embodiment according to FIG. 3, the at least one waveguide 6 is optionally arranged such that the actual tilt of the optical surface 3 is determinable by way of a measurement of the deformation of an element 10 connected to the optical element 2.

In this case, the measurement section 7 is optionally arranged, at least in part, in the element 10 connected to the optical element 2.

In the exemplary embodiment depicted in FIG. 3, the connected element 10 is optionally embodied as spring element 11, to which the optical element 2 is connected or on which the optical element 2 is arranged.

Provision can also be made for embodiments in which the connected element 10 is a spring element 11, to which the optical element 2 is connected indirectly, e.g. via a further intermediate element, or on which the optical element 2 is formed directly.

In the exemplary embodiment depicted in FIG. 3, the measuring device 5 comprises a path length measuring device 12 for sensing a change in length of the measurement section 7 provided by the waveguide 6. Further, the measuring device 5 is configured to determine the actual tilt of the optical surface 3 from the change in length.

In the exemplary embodiment depicted in FIG. 3, the path length measuring device 12 optionally comprises at least one grating device for the measurement radiation, the at least one grating device optionally being in the form of a fiber Bragg grating 13 in the illustrated exemplary embodiment.

In the exemplary embodiment depicted in FIG. 3, provision is made for a closed-loop control device 14 with a control loop, optionally a closed-loop control circuit, for the purpose of setting a target tilt of the optical surface 3 via the actuators 4, with an actual tilt of the optical surface 3 ascertained by the measuring device 5 being taken into account. In FIG. 3, the connection between the closed-loop control device 14, the measuring device 5 and the actuators 4 is depicted using dashed lines.

In the exemplary embodiment depicted in FIG. 3, the measuring device 5 optionally comprises at least two waveguides 6 which each form a closed measurement section 7, with the measurement sections 7 being arranged such that an actual tilt of the optical surface 3 about a first axis 15 is able to be sensed via a first measurement section 7a and an actual tilt of the optical surface 3 about a second axis 16 running orthogonal to the first axis 15 is able to be sensed via a second measurement section 7b. In this case, the two axes 15, 16 run below the optical surface 3 in a plane of the spring elements 11.

In the exemplary embodiment depicted in FIG. 3, the plane of the spring elements 11, in which the two axes 15, 16 run, is arranged at a distance from and plane parallel with the rest position of the optical surface 3.

In FIG. 3, the axes 15 and 16 are only indicated in the middle of the optical apparatus 1. In fact, the axes 15, 16, as virtual axes, each extend to infinity in both directions.

FIG. 4 shows a schematic illustration of a possible embodiment of the optical apparatus 1 as field facet mirror 119 and/or pupil facet mirror 121, which comprises a plurality of optical elements 2 in the form of micromirrors 2a, with the optical surfaces 3 being formed as reflective planes, each of which being tiltable about two axes which extend orthogonal to one another.

FIG. 4 thus shows an exemplary embodiment in which the plurality of optical elements 2 of the optical apparatus 1 are in the form of micromirrors 2a.

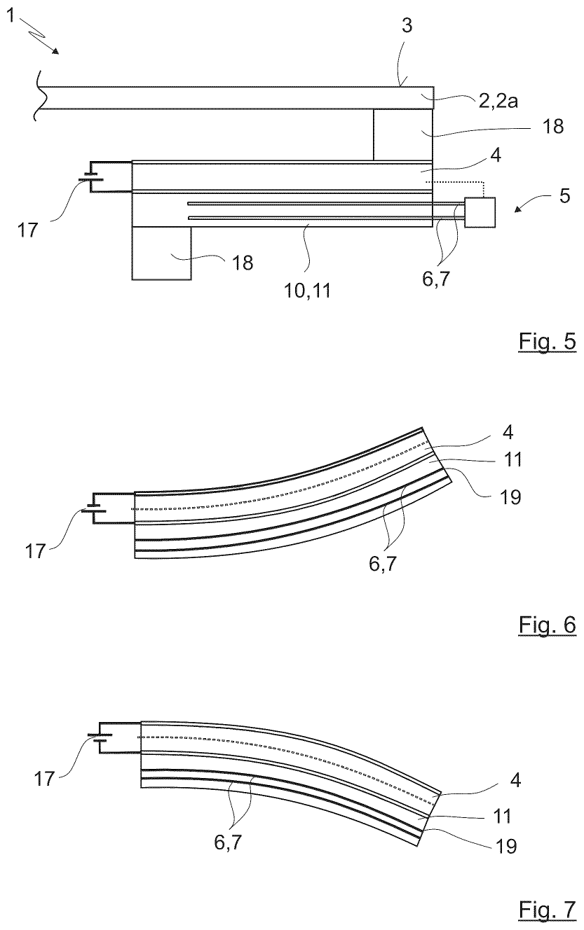

FIG. 5 shows a schematic illustration of a section through a part of a further possible embodiment of the optical apparatus 1.

In the embodiment depicted in FIG. 5, the measuring device 5 optionally comprises a plurality of waveguides 6 (two being depicted). The waveguides 6 each form a closed measurement section 7, with at least two of the waveguides 6 being formed in or extending at different or differing depths in the spring element 11. In the spring element 11, the waveguides 6 are thus arranged offset from one another in the depth direction.

In the exemplary embodiment depicted in FIG. 5, the actuator 4 is in the form of a piezoelectric layer, and a voltage source 17 is provided and configured for supplying the actuator 4 with a voltage.

FIG. 5 also depicts connector elements 18, which connect the optical element 2 to the actuator 4 or the spring element 11 to a stationary base (not depicted here).

FIG. 6 shows a schematic illustration of a part of the embodiment of the optical apparatus 1 according to FIG. 5 in an upwardly deflected state or in a state deflected in the direction toward the optical element 2. As depicted in FIG. 6, at least the spring element 11 is deflected upwardly. In this case, the deflection is the result of an appropriate control of the actuator or actuators 4, whereby a desired target tilt of the optical surface 3 is intended to be set or, in general, a tilt of the optical surface 3 is intended to be achieved.

In the exemplary embodiment according to FIGS. 5 to 7, provision is made for the illustration as per FIG. 5 to show a rest position of the optical surface 3 or of the spring element 11. In this rest position, provision is optionally made for the two waveguides 6 to have an identical length.

In the exemplary embodiment depicted in FIG. 6, at least one of the waveguides 6 is arranged in a strain-neutral plane 19 of the spring element 11 and at least one of the waveguides 6 is arranged in or on the spring element 11 in such a way that the length of the waveguide 6 changes when the optical surface 3 tilts or the length of the waveguide 6 is modified in comparison with a rest position when a target tilt of the optical surface 3 is set or an actual tilt is obtained. In the exemplary embodiment according to FIGS. 5 to 7, provision can be made for the strain-neutral plane 19 to extend centrally in the spring element 11 with regards to the depth direction, with the result that the correspondingly arranged waveguide 6 is likewise optionally arranged centrally (in the depth direction) in the spring element 11.

FIG. 7 shows a schematic illustration according to FIG. 6 in a downwardly deflected state. In respect of the reference signs, reference is made to the description relating to FIG. 6.

In the embodiment depicted in FIGS. 6 and 7, the actuator 4 in the form of a piezo layer also comprises a plane, which is depicted as a dashed line in FIGS. 6 and 7 and in which a measurement section 7 could be arranged.

The embodiment according to FIGS. 5, 6 and 7 accordingly shows such an arrangement of the at least one waveguide 6 that the actual tilt of the optical surface 3 is determinable by measuring the deformation or the tilt or the bending of an element 10, in this case of the spring element 11, connected to the optical element 2.

In an alternative embodiment (not depicted here), the at least one waveguide 6 can also be arranged such that the actual tilt of the optical surface 3 is determinable by measuring the deformation or the tilt or the bending of the optical element 2 itself.

Further, the measurement section 7 in the embodiment according to FIGS. 5, 6 and 7 is arranged in the element 10, the spring element 11 in this case, connected to the optical element 2. In a further embodiment not depicted here, the measurement section 7 can be arranged, at least in part, in and/or on the optical element 2.

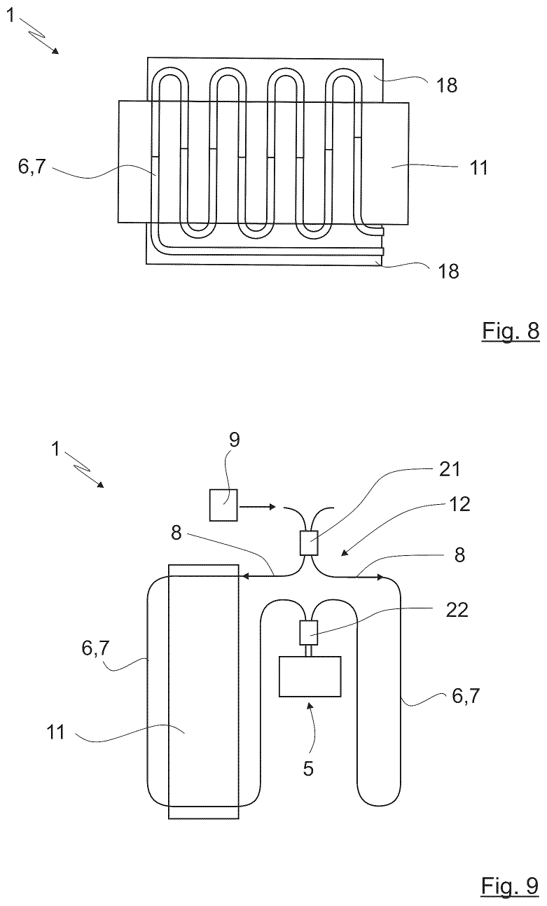

FIG. 8 shows a schematic illustration of a plan view of a part of the embodiment of the optical apparatus 1 according to FIG. 5. In the exemplary embodiment depicted in FIG. 8, the waveguide 6 forming the closed measurement section 7 has a meandering embodiment or extends in the spring element 11 in meandering fashion. In this case, the straight portions of the meander-like loops of the waveguide 6 extend along the direction of greatest deformation of the spring element 11. The loops of the waveguide 6 depicted in FIG. 8 might just as well also be arranged in the strain-neutral plane 19 of the spring element 11. In the exemplary embodiment depicted in FIG. 8, provision is optionally made for the (optionally two) waveguides 6 to be arranged such that one of the waveguides 6 extends in the strain-neutral plane 19 of the spring element 11 and the other waveguide 6 is arranged in or on the spring element 11 such that the length of the waveguide 6 changes when the optical surface 3 tilts, as depicted in FIGS. 6 and 7. Optionally, all waveguides 6 can be arranged extending in meandering fashion here.

The waveguide 6 forming the closed measurement section 7 extending in the strain-neutral plane 19 of the spring element 11 can be used for a reference measurement, the result of which is then compared with the measurement result of the closed measurement section 7 of the waveguide 6 or waveguides 6 not extending in the strain-neutral plane 19.

FIG. 9 shows a schematic illustration of a part of a further possible embodiment of the optical apparatus 1.

In the exemplary embodiment depicted in FIG. 9, the path length measuring device 12 is configured to split the optionally coherent measurement radiation into at least two measurement beams 8 and make these interfere.

In an alternative to that or in addition, provision can be made for the path length measuring device 12 to be configured to split the optionally coherent measurement radiation into at least two measurement beams 8 and to create a measurement spectrum of the measurement radiation.

In the exemplary embodiment depicted in FIG. 9, the path length measuring device 12 comprises a power splitter 21 which is configured and arranged to split the measurement radiation formed by the radiation source 9 into at least two measurement beams 8 and input couple the measurement beams 8 into a respective waveguide 6 forming a measurement section 7, with the path length measuring device 12 comprising a power combiner 22 which is configured and arranged to recombine the measurement beams 8 following their propagation through the respective waveguides 6. In this case, the measuring device 5 is configured to sense the superimposed measurement beams 8.

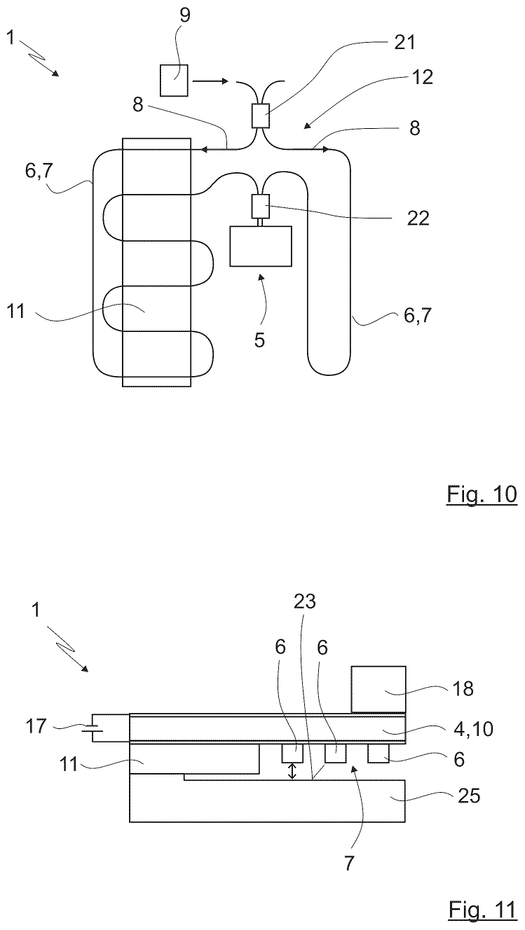

FIG. 10 shows a schematic illustration of a modification of the embodiment according to FIG. 9.

In the embodiment depicted in FIG. 10, one of the two waveguides 6 or one of the two measurement sections 7 is arranged in a manner extending over the spring element 11 in meandering fashion. A similar arrangement of the waveguide 6 or of the measurement section 7 is also depicted in FIG. 8.

In FIGS. 9 and 10, the measuring device 5 is in the form of an integrated photonic circuit which comprises a Mach-Zehnder interferometer.

In the exemplary embodiment depicted in FIG. 9, the measuring device 5 comprises a Mach-Zehnder interferometer, in which one arm of the Mach-Zehnder interferometer experiences a change in length and thus is formed as a measurement arm. The other arm depicted on the right-hand side in FIG. 9, by contrast, is static and thus formed as a reference arm. The waveguide 6 forming the measurement arm is at least partly integrated in a deforming part of the spring element 11 on the left-hand side of FIG. 9. The static reference arm, by contrast, is integrated in a stiff region of the optical apparatus 1, optionally also in the neutral plane 19 of the spring element 11.

FIG. 10 shows a special embodiment of FIG. 9, wherein the waveguide 6 in the measurement arm arranged to the left is integrated in meandering fashion in a deforming part of the spring element 11 in order to increase an accumulated change in length.

In the exemplary embodiment depicted in FIG. 10, the measurement arm arranged on the left has N=6 passages in a bending direction of the spring element 11.

FIG. 11 shows a schematic illustration of a part of a further possible embodiment of the optical apparatus 1.

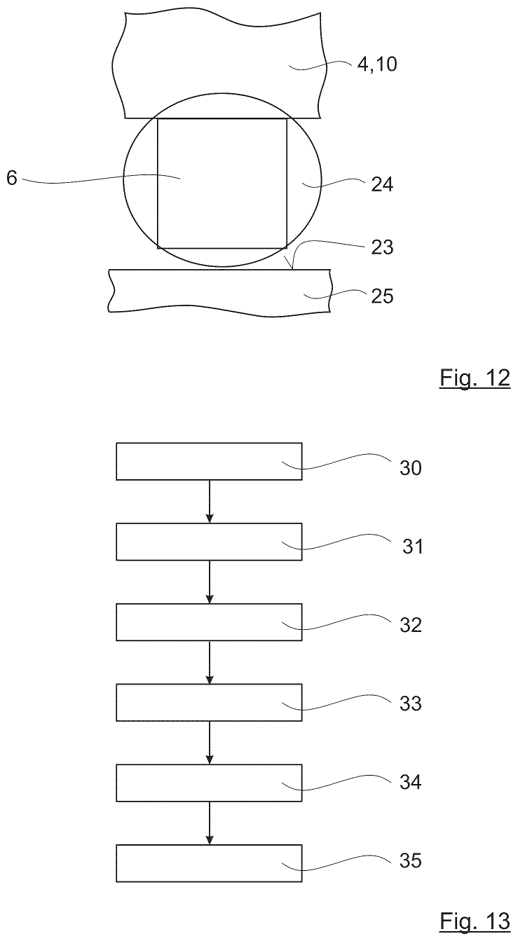

In the embodiment of the optical apparatus 1 depicted in FIG. 11, the at least one waveguide 6 is arranged and configured such that as a result of an actual tilt of the optical surface 3 the waveguide 6 approaches or retreats from a reference region 23 situated in the direct vicinity of the waveguide 6, in such a way that the reference region 23 influences an evanescent field 24 (see FIG. 12) emerging from the waveguide 6, and the measuring device 5 is configured to measure the influence.

In the above-described exemplary embodiments, the measuring device 5 is configured in each case to ascertain the actual tilt of the waveguide 6 from an interference pattern of the measurement beam 8 or measurement beams 8 and/or ascertain the actual tilt of the waveguide 6 from a measurement beam 8 and/or measurement radiation transmittance.

In the exemplary embodiment depicted in FIG. 11, the at least one waveguide 6 is arranged on an element 10 connected to the optical element, in this case arranged on the actuator 4, and the at least one reference region 24 is stationary.

Alternative or additional embodiments (not depicted here) can provide for the at least one waveguide 6 to be arranged on the optical element 2 and/or for the at least one waveguide 6 to be arranged on another connected element, for example the spring element 11. In this case, too, provision is optionally made for the at least one reference region 24 to be stationary.

In the exemplary embodiment depicted in FIG. 11, the reference region 23 is further arranged on a stationary base region 25, for example a substrate.

In a further embodiment to be realized in addition or as an alternative in the optical apparatus 1, provision can be made for the at least one reference region 23 to be arranged on the optical element 2 and/or for the at least one reference region 23 to be arranged on the connected element 10, for example the spring element 11 or the actuator 4, and for the at least one waveguide 6 to be arranged stationarily.

Optionally, in the exemplary embodiment depicted in FIG. 11, the at least one waveguide 6 is arranged such that the actual tilt of the optical surface 3 is determinable by way of a measurement of the translation of the element 10 connected to the optical element 2.

In an alternative embodiment, the at least one waveguide 6 can be arranged on the optical element 2 such that the actual tilt of the optical surface 3 is determinable by measuring the translation of the optical element 2.

Further, the measurement section 7 in FIG. 11 is arranged, at least in part, on the element 10 connected to the optical element 2. In an alternative embodiment, provision is made for the measurement section 7 to be arranged, at least in part, on the optical element 2.

FIG. 12 shows an enlarged illustration of a detail from FIG. 11.

From FIG. 12, it is evident how the evanescent field 24, which emerges from the waveguide 6, is able to interact with the reference region 23 in the direct vicinity of the waveguide 6. An arrangement of the reference region 23 in the direct vicinity of the waveguide 6 can be desirable on account of the fast decay of the evanescent field 24 with increasing distance from the waveguide 6, whereby it is possible to obtain a high spatial resolution.

In the embodiments of the optical apparatus 1 depicted in FIGS. 3 to 12, the constituent parts can be embodied as integrated photonic component parts. For example, the at least one waveguide 6 can be in the form of a dielectric monomode waveguide. The power splitter 21 and/or the power combiner 22 can be in the form of multi-mode interference couplers. The radiation source 9 can be in the form of a laser. Output coupling structures for vertical output coupling of the light, for example grating couplers or prism couplers, may be provided for output coupling the measurement beam from the waveguide 6.

The above-described component parts can be formed by semiconductor production processes for photonic integrated circuits (PICs). For example, the at least one waveguide 6 made of silicon can be formed in structured fashion on a silicon-on-insulator (SOI) wafer. Further, waveguides 6 made of silicon nitrite are able to be formed on SOI substrates or waveguides from the III-V semiconductor group are able to be formed on corresponding substrates. Optionally, use of what is known as SOI-PIC technology can be provided.

The radiation source 9 can be integrated as a laser in a photonic plane in a wafer-level process, for example by transfer printing and/or a flip-chip bonding process. As an alternative to that or in addition, use can be made of external radiation sources 9 that are not integrated on a chip of the optical apparatus 1. The measurement radiation from such an external radiation source 9 is then divided among measurement beams 8 or distributed to the respective measurement sections 7, optionally by way of an integrated distribution network. In this case, the external measurement radiation is optionally supplied from a lower side of a stationary base region, for example of the base region 25 or of the substrate forming the base region 25, in order to ensure a high fill factor during use in a field facet mirror 119 and/or pupil facet mirror 121. To this end, the use of a transparent substrate and/or the formation of holes or drilled holes in the substrate (optical through silicon vias) can be provided. In an alternative to that or in addition, input coupling of the measurement radiation into the optical apparatus 1 and/or into the measurement section 7 can be provided from an edge of the optical apparatus 1.

In the exemplary embodiments depicted in FIG. 3 and FIGS. 5 to 12, the spring element 11 is optionally formed as a silicon membrane.

In the exemplary embodiments depicted in FIGS. 11 and 12, the effective refractive index of the optical mode of the measurement beam 8, which propagates in the waveguide 6 optionally formed as a silicon membrane, depends on a distance between the waveguide 6 and the reference region 23, wherein the reference region 23 can be in the form of a silicon block. From FIG. 12, it is evident that the described change in the mode index is caused by the evanescent component of the electric field of the measurement beam 8 overlapping with the reference region 23, for example the silicon block.

An implementation of such an embodiment of the waveguide 6 in an integrated interferometric and/or resonant structure allows the realization of a very sensitive proximity sensor, via which it is possible in turn to determine the deformation of the actuator 4 in the form of the piezoelectric layer.

As indicated in FIG. 11, a grid of waveguides 6 may be provided in order to ensure a high spatial resolution over a sufficiently large measurement region. In the case of a deflection of the piezoelectric layer, the individual waveguides 6 in FIG. 11 adopt different distances from the reference region 23, with the result that a respective one of the waveguides 6 is always arranged at an optimal measurement distance from the reference region 23 when the deflection is changed.

It is possible to manage without a free beam propagation of the measurement beam 8 in the exemplary embodiments depicted in FIGS. 11 and 12.

The embodiments of the optical apparatus 1 depicted in FIGS. 3 to 12 are suitable for carrying out a method for measuring the actual tilt of the optical surface 3 of the optical element 2.

FIG. 13 shows a block diagram-like illustration of a possible embodiment of a method for measuring an actual tilt of the optical surface 3 of the optical element 2.

In the method for measuring the actual tilt of the optical surface 3 of the optical element 2, for example of a lithography system and especially of a projection exposure apparatus 100, 200 for semiconductor lithography in this context, the actual tilt of the optical surface 3 is determined by the at least one measurement beam 8 which propagates along the measurement section 7, with the one or more actuators 4 being arranged to influence the tilt of the optical surface 3. Further, a closed measurement section 7 is formed by at least one waveguide 6, with the measurement beam 8 being input coupled into the waveguide 6 such that one or more modes of the measurement beam 8 propagate through the waveguide 6. In this case, the waveguide 6 is arranged such that the measurement beam 8 propagating through the waveguide 6 is influenced by a tilt of the optical surface 3, with the influence on the measurement beam 8 effected by the tilt of the optical surface 3 being sensed and the actual tilt of the optical surface 3 being determined therefrom.

Optionally, the method according to the disclosure can be performed as set forth below.

The closed measurement section 7 is formed by the at least one waveguide 6 in a measurement section block 30.

The one or more actuators 4 are arranged in an arrangement block 31, in order to influence the tilt of the optical surface 3.

The waveguide 6 is arranged such that the measurement beam 8 propagating through the waveguide 6 is influenced by a tilt of the optical surface 3.

In an input coupling block 32, the measurement beam 8 is input coupled into the waveguide 6 in such a way that one or more modes of the measurement beam 8 propagate through the waveguide 6.

In an influencing block 33, the measurement beam 8 propagating through the waveguide 6 is influenced by the tilt of the optical surface 3.

The influence on the measurement beam 8 caused by the tilt of the optical surface 3 is sensed in a sensing block 34.

The actual tilt of the optical surface 3 is determined from the sensed influence in a determination block 35.

In the method, the actual tilt of the optical surface 3 is accordingly determined by the at least one measurement beam 8 which propagates along the measurement section 7.

In the arrangement block 31, provision can be made for the at least one actuator 4 to be formed by a microelectromechanical system, and/or for the at least one optical element 2 to be formed by a micromirror 2a.

As part of the influencing block 33, provision can be made for a change in length of the measurement section 7 provided by the waveguide 6 to be caused by the actual tilt of the optical surface 3.

As a part of the sensing block 34, provision can be made for the change in length of the measurement section 7 provided by the waveguide 6 to be sensed. As part of the determination block 35, provision can be made for the actual tilt of the optical surface 3 to be determined from the change in length.

In the sensing block 34, provision can be made for a path length difference of the measurement beam 8 propagating through the waveguide 6 to be measured, the path length difference being caused by the actual tilt of the optical surface 3. For example, provision can be made for an interference pattern, for example the measurement spectrum, of the measurement beam 8 to be ascertained.

As part of the determination block 35, provision can be made for the change in length of the waveguide 6 to be determined from a phase of the measurement beam 8.

As part of the measurement section block 30, provision can be made for two or more waveguides 6 to be arranged in a spring element 11 and for the spring element 11 to be an element 10 connected to the optical element 2, with the at least two waveguides 6 being arranged at different depths within the spring element 11.

As part of the measurement section block 30, provision can be made for at least one of the waveguides 6 to be arranged in the strain-neutral plane 19 of the spring element 11 and for at least one of the waveguides 6 to be arranged in or on the spring element 11 such that, within the scope of the influencing block 33, the length of the waveguide 6 changes when the optical surface 3 tilts.

As part of the sensing block 34, provision can be made for the change in length of the at least two waveguides 6 to be sensed at different depths in the spring element 11.

As part of the determination block 35, provision can be made for the respective actual tilt to be determined from the change in length of the waveguides 6 at different depths in the spring element 11 which holds the optical element 23 or the optical surface 3.

Within the scope of the input coupling block 32, provision can be made for the measurement radiation to be divided among at least two measurement beams 8 and for the measurement beams 8 to be input coupled into a respective waveguide 6 forming a measurement section 7.

Within the scope of the sensing block 34, provision can be made for the measurement beams 8 to be combined again following the propagation through the respective waveguide 6 and for the superimposed measurement beams 8, for example the power of the superimposed measurement beams 8, to be sensed, for example detected by a photodetector.

Within the scope of the input coupling block 32 and/or the measurement section block 30, provision can be made for a first measurement beam 8 in a first measurement section 7 to be guided through a region which is deformed when the optical surface 3 tilts, for example through a flexible region of the spring element 11, with a second measurement beam 8 in a second measurement section 7 being guided through a region which remains stiff or is not deformed or deformed differently during the tilt of the optical surface 3, for example through a stiff region of the optical element 2. Optionally, provision is made for the measurement beams 8 to be guided within a common plane.

Within the scope of the determination block 35, provision can be made for the actual tilt of the optical surface 3 to be determined from the measured data of the measurement beams 8.

In an alternative or in addition to that, provision can be made within the scope of the measurement section block for the at least one waveguide 6 to be arranged and configured such that as a result of an actual tilt of the optical surface 3 the waveguide 6 is made to approach or retreat from the reference region 23 situated in the direct vicinity of the waveguide 6, in such a way that, within the scope of the influencing block 33, the reference region 23 influences the evanescent field 24 emerging from the waveguide 6, and, within the scope of the sensing block 34, the influence is measured and, within the scope of the determination block 35, the actual tilt of the optical surface 3 is determined therefrom.

Within the scope of the determination block 35, provision can be made for the actual tilt of the optical surface 3 vis-à-vis the reference region 23 to be ascertained from an interference pattern of the measurement beams 8, and/or for the actual tilt of the optical surface 3 to be ascertained from a transmission of the measurement beam 8.

The embodiments of the optical apparatus 1 depicted in FIGS. 3 to 12 and the method sketched out in the context of FIG. 13 are suitable for use in a lithography system.

For example, the lithography system can be a projection exposure apparatus, for example the projection exposure apparatus 100, 200 for semiconductor lithography (see FIG. 1 and FIG. 2). In this case, provision can be made for an illumination system 101, 201 with a radiation source 102 and an optical unit 103, 109, 206 which comprises at least one optical element 116, 118, 119, 120, 121, 122, Mi, 207. Further, at least one optical apparatus 1 as per at least one of the exemplary embodiments is provided in the lithography system, with at least one of the optical elements 116, 118, 119, 120, 121, 122, Mi, 207 being an optical element 2 of the at least one optical apparatus 1. In an alternative to that or in addition, at least one of the optical elements 116, 118, 119, 120, 121, 122, Mi, 207 comprises an optical surface 3, the actual tilt of which is ascertained using at least one embodiment of the method.

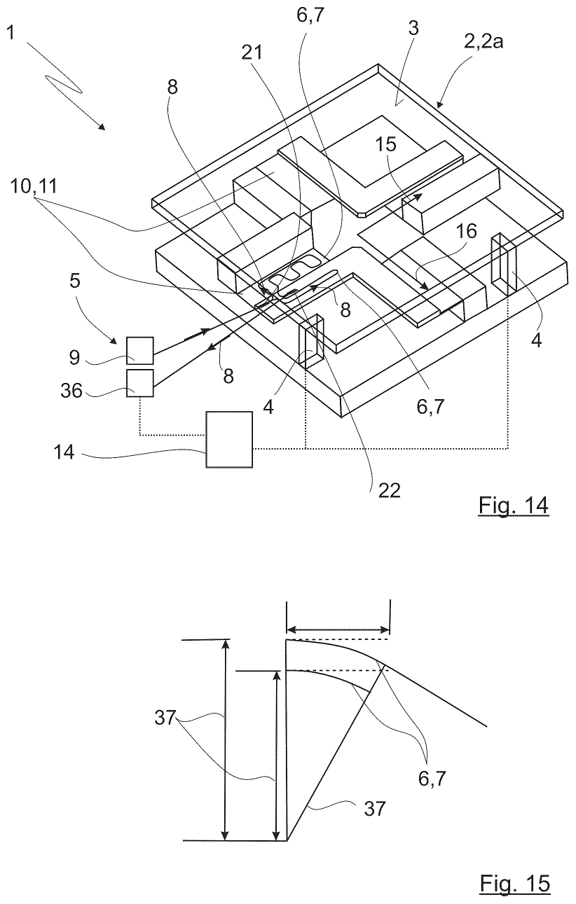

FIG. 14 shows a schematic illustration of a further possible embodiment of the optical apparatus 1.

The measuring device 5 comprises at least two waveguides 6. In this case, at least a first waveguide 6 is arranged in a region which is deformed when the optical surface 3 is tilted, for example arranged in a flexible region of the spring element 11. Further, at least a second waveguide 6 is arranged in a region which is stiff or not deformed when the optical surface 3 is tilted, for example arranged in a stiff region of the optical element 2.

In the exemplary embodiment depicted in FIG. 14, the waveguides 6 are optionally arranged in a common plane.

In the exemplary embodiment depicted in FIG. 14, the common plane is arranged spaced apart from and plane parallel with respect to the rest position of the optical surface 3.

Formulated more abstractly, the measuring device 5 in the exemplary embodiment depicted in FIG. 14 comprises at least two waveguides 6, wherein at least one first waveguide 6 is arranged in a first region which is deformed when the optical surface 3 tilts, for example arranged in a first flexible region of the spring element 11, while at least one second waveguide 6 is arranged in a second region which is deformed differently to the first region, for example not deformed at all, when the optical surface 3 tilts. In this case, the waveguides 6 are optionally arranged in a common plane.

Further, a sensing device 36 in the form of a photodetector is provided in FIG. 14 for the purpose of sensing a radiation formed by the superimposed measurement beams 8.

With regards to the reference signs depicted in FIG. 14, reference is made to the explanations given in the context of FIG. 3.

FIG. 15 shows a schematic illustration of a possible arrangement of two measurement sections 7 in the spring element 11.

In the exemplary embodiment depicted in FIG. 15, at least two waveguides 6 are present and arranged in different planes in each case, depicted using dashed lines, of the spring element 11 (not depicted here), wherein a different strain occurs in the various planes when the optical surface 3 is tilted.

This results in different radii of curvature 37 for the waveguides 6 in a deformed portion 38.

### LIST OF REFERENCE SIGNS

1 Optical apparatus
2 Optical element
2a Micromirror
3 Optical surface
4 Actuator
5 Measuring device
6 Waveguide
7 Closed measurement section
7a First measurement section
7b Second measurement section
8 Measurement beam
9 Radiation source
10 Connected element
11 Spring element
12 Path length measuring device
13 Fiber Bragg grating
14 Closed-loop control device
15 First axis
16 Second axis
17 Voltage source
18 Connector element
19 Strain-neutral plane
21 Power splitter
22 Power combiner
23 Reference region
24 Evanescent field
25 Base region
30 Measurement section block
31 Arrangement block
32 Input coupling block
33 Influencing block
34 Sensing block
35 Determination block
36 Sensing device
37 Radius of curvature
38 Deformed portion
100 EUV projection exposure apparatus
101 Illumination system
102 Radiation source
103 Illumination optical unit
104 Object field
105 Object plane
106 Reticle
107 Reticle holder
108 Reticle displacement drive
109 Projection optical unit
110 Image field
111 Image plane
112 Wafer
113 Wafer holder
114 Wafer displacement drive
115 EUV/used/illumination radiation
116 Collector
117 Intermediate focal plane
118 Deflection mirror
119 First facet mirror/field facet mirror
120 First facets/field facets
121 Second facet mirror/pupil facet mirror
122 Second facets/pupil facets
200 DUV projection exposure apparatus
201 Illumination system
202 Reticle stage
203 Reticle
204 Wafer
205 Wafer holder
206 Projection optical unit
207 Lens element
208 Mount
209 Lens housing
210 Projection beam
Mi Mirrors

What is claimed is:

1. An optical apparatus, comprising:
an optical element comprising an optical surface;
an actuator configured to tilt the optical surface; and
a measuring device configured to sense a tilt of the optical surface from a rest position,
wherein:
the measuring device comprises a waveguide defining a closed measurement section;
the waveguide is configured to input couple and allow propagation of a mode of a measurement beam;
the waveguide is configured so that a tilt of the optical surface influences the measurement beam when the measurement beam propagates through the waveguide; and
the measuring device is configured to sense an influence on the measurement beam caused by the tilt of the optical surface.

2. The optical apparatus of claim 1, wherein the waveguide is configured so that an actual tilt of the optical surface is determinable via a measurement of a translation or a deformation of the optical element or of a translation or a deformation of an element connected to the optical element.

3. The optical apparatus of claim 2, wherein the connected element comprises a spring connected to the optical element at least indirectly and/or on which the optical element is arranged and/or formed.

4. The optical apparatus of claim 3, wherein the waveguide is in a strain-neutral plane of the spring, and the waveguide is in or on the spring element so that a length of the waveguide changes when the optical surface tilts.

5. The optical apparatus of claim 1, wherein the measuring device comprises a path length measuring device configured to sense a change in a length of the measurement section, and the measuring device is configured to determine an actual tilt of the optical surface based on the change in length.

6. The optical apparatus of claim 5, wherein the path length measuring device is configured to split the measurement radiation into two measurement beams such that: i) the measurement beams interfere; and/or ii) the measurement beams create a measurement spectrum of the measurement radiation.

7. The optical apparatus of claim 5, wherein the path length measuring device comprises a grating device configured for the measurement radiation.

8. The optical apparatus of claim 1, wherein the waveguide is configured so that, due to a tilt of the optical surface, the waveguide moves relative to a reference region in direct vicinity to the waveguide so that the reference region influences an evanescent field emerging from the waveguide, and the measuring device is configured to measure the influence.

9. The optical apparatus of claim 1, wherein the measuring device is configured to ascertain an actual tilt of the waveguide based on an interference pattern of the measurement beam, and/or the measuring device is configured to ascertain the actual tilt of the waveguide based on a measurement beam transmittance.

10. The optical apparatus of claim 1, wherein:
the measuring device comprises a first waveguide comprising a first measurement section and a second waveguide comprising a second measurement section;
each waveguide defines a closed measurement section;
the measurement sections is configured so that an actual tilt of the optical surface about a first axis is able to be sensed via the first measurement section;
an actual tilt of the optical surface about a second axis orthogonal to the first axis is able to be sensed via the second measurement section.

11. The optical apparatus of claim 1, further comprising:
an actuator; and
a closed-loop control device comprising a control loop configured to set a target tilt of the optical surface via the actuator,
wherein the optical apparatus is configured so that an actual tilt of the optical surface ascertained by the measuring device is taken into account.

12. The optical apparatus of claim 1, comprising a plurality of optical elements, and the optical elements comprise micromirrors.

13. The optical apparatus of claim 1, wherein:
the optical apparatus comprises a mirror selected from the group consisting of a field facet mirror and a pupil facet mirror;
the mirror comprises a plurality of micromirrors;
an optical surface of each micromirror comprises a reflective plane tiltable about two axes.

14. A system, comprising:
an illumination system; and
a projection optical unit comprising an optical apparatus according to claim 1,
wherein the system is a semiconductor lithography projection exposure apparatus.

15. A method of measuring an actual tilt of an optical surface of an optical element of a semiconductor lithography projection exposure apparatus via a measurement beam propagating along a closed measurement section defined by a waveguide, the optical surface being tiltable via an actuator, the method comprising:
input coupling the measurement beam into the waveguide so that a mode of the measurement beam propagates through the waveguide so that the measurement beam propagating through the waveguide is influenced based on a tilt of the optical surface;
sensing the influence on the measurement beam caused by the actual tilt of the optical surface; and
determining the actual tilt of the optical surface based on the sensed influence on the measurement beam.

16. The method of claim 15, wherein the actuator comprises a microelectromechanical system, and/or the optical element comprises a micromirror.

17. The method of claim 15, comprising sensing a change in length of the measurement section, and determining the actual tilt of the optical surface based on the change in length.

18. The method of claim 15, comprising determining a change in length of the waveguide based on a phase of the measurement beam.

19. The method of claim 15, comprising:
a) splitting a measurement radiation into first and second measurement beams;
b) coupling the first measurement beam into a first waveguide defining a first measurement section and propagating the first measurement beam through the first waveguide;
c) coupling the second measurement beam into a second waveguide defining a second measurement section and propagating the second measurement beam through the second waveguide;
d) after b) and c), combining the first and second measurement beams to provide a combined measurement beam; and
e) sensing a power of the combined measurement beam to determine the actual tilt of the optical surface.

20. The method of claim 15, wherein:
the waveguide is configured so that, due to a tilt of the optical surface, the waveguide moves relative to a reference region in direct vicinity to the waveguide so that the reference region influences an evanescent field emerging from the waveguide; and
the method comprises measuring the influence to determine the actual tilt of the optical surface.
